(19) United States
(12) Patent Application Publication
(10) Pub. No.: US 2026/0190706 A1
(43) Pub. Date: Jul. 2, 2026

(54) DISPLAY DEVICE AND ELECTRONIC DEVICE INCLUDING THE SAME

(71) Applicant: Samsung Display Co., Ltd., Yongin-si (KR)

(72) Inventors: Seung-Jun LEE, Yongin-si (KR); Jaewoo LEE, Yongin-si (KR); Gun Hee KIM, Yongin-si (KR); Sang-Hee JANG, Yongin-si (KR); Sunyoung JUNG, Yongin-si (KR)

(73) Assignee: Samsung Display Co., Ltd., Yongin-si (KR)

(21) Appl. No.: 19/381,291

(22) Filed: Nov. 6, 2025

(30) Foreign Application Priority Data
Dec. 31, 2024 (KR) 10-2024-0201587

(51) Int. Cl. H10K 59/131

(52) U.S. Cl. CPC H10K 59/131

(57) ABSTRACT

A display device includes a first power supply voltage wiring in a first region and configured to provide a first power supply voltage; a second power supply voltage wiring in a second region and configured to provide a second power supply voltage, and a plurality of power supply voltage supply-lines in the first region, the second region, and a boundary region between the first region and the second region. Here, a number of contact holes connecting the first power supply voltage wiring and the power supply voltage supply-lines in a first row of the boundary region is different from a number of contact holes connecting the first power supply voltage wiring and the power supply voltage supply-lines in a first row of the first region.

### CROSS-REFERENCE TO RELATED APPLICATION

This application is based on and claims priority to Korean Patent Application No. 10-2024-0201587, filed on Dec. 31, 2024, in the Korean Intellectual Property Office, the disclosure of which is herein incorporated by reference in its entirety.

### BACKGROUND

### 1. Field

Embodiments of the present disclosure relate to a display device and an electronic device including the display device.

### 2. Description of Related Art

A display device includes a display panel and a driving circuit. Pixels are disposed in the display panel. The driving circuit supplies signals and/or voltages to the display panel.

For example, the driving circuit includes a data driving circuit, a gate driving circuit, and a power supply circuit. The data driving circuit supplies a data voltage to the display panel, the gate driving circuit supplies a gate signal to the display panel, and the power supply circuit supplies a power supply voltage to the display panel. The display panel emits light corresponding to the data voltage in response to the gate signal.

### SUMMARY

An object of the present disclosure is to provide a display device.

Another object of the present disclosure is to provide an electronic device including the display device.

However, objects of the present disclosure are not limited to the above objects, and may be variously extended without departing from the spirit and scope of the present disclosure.

According to an aspect of one or more example embodiments, provided is a display device including: a first power supply voltage wiring in a first region of a display panel, the first power supply voltage wiring configured to provide a first power supply voltage, and extending in a row direction; a second power supply voltage wiring in a second region of the display panel, the second power supply voltage wiring configured to provide a second power supply voltage, and extending in the row direction; and a plurality of power supply voltage supply-lines in the first region, the second region, and a boundary region between the first region and the second region, the plurality of power supply voltage supply-lines extending in a column direction, wherein a number of first contact holes connecting the first power supply voltage wiring and the plurality of power supply voltage supply-lines in a first row of the boundary region is different from a number of second contact holes connecting the first power supply voltage wiring and the plurality of power supply voltage supply-lines in a first row of the first region, and wherein a number of third contact holes connecting the second power supply voltage wiring and the plurality of power supply voltage supply-lines in a second row of the boundary region is different from a number of fourth contact holes connecting the second power supply voltage wiring and the plurality of power supply voltage supply-lines in a second row of the second region.

According to an aspect of one or more example embodiments, provided is a display device including: a plurality of first-first power supply voltage wirings in a first region of a display panel, the plurality of first-first power supply voltage wirings configured to provide a first power supply voltage, and extending in a row direction; a plurality of second-first power supply voltage wirings in a second region of the display panel, the plurality of second-first power supply voltage wirings configured to provide a second power supply voltage, and extending in the row direction; a plurality of first-second power supply voltage wirings in a boundary region between the first region and the second region, the plurality of first-second power supply voltage wirings and extending in the row direction; and a plurality of first power supply voltage supply-lines configured to provide the first power supply voltage to the plurality of first-first power supply voltage wirings and the plurality of first-second power supply voltage wirings, wherein, in the boundary region, a number of first contact holes connecting the plurality of first power supply voltage supply-lines and the plurality of first-second power supply voltage wirings decreases in a direction from the first region to the second region.

According to embodiments, an electronic device a display device configured to display an image; and a power supply configured to supply power supply voltages to the display device, wherein the display device includes: a first power supply voltage wiring in a first region of a display panel, the first power supply voltage wiring configured to provide a first power supply voltage, and extending in a row direction; a second power supply voltage wiring in a second region of the display panel, the second power supply voltage wiring configured to provide a second power supply voltage, and extending in the row direction; and a plurality of power supply voltage supply-lines in the first region, the second region, and a boundary region between the first region and the second region, the plurality of power supply voltage supply-lines extending in a column direction, wherein a number of first contact holes connecting the first power supply voltage wiring and the plurality of power supply voltage supply-lines in a first row of the boundary region is different from a number of second contact holes connecting the first power supply voltage wiring and the plurality of power supply voltage supply-lines in a first row of the first region, and wherein a number of third contact holes connecting the second power supply voltage wiring and the plurality of power supply voltage supply-lines in a second row of the boundary region is different from a number of fourth contact holes connecting the second power supply voltage wiring and the plurality of power supply voltage supply-lines in a second row of the second region.

### BRIEF DESCRIPTION OF DRAWINGS

Illustrative, non-limiting embodiments will be more clearly understood from the following detailed description in conjunction with the accompanying drawings.

FIG. 1 is a block diagram illustrating an example of a display device according to one or more embodiments.

FIG. 2 is a block diagram illustrating another example of a display device according to one or more embodiments.

FIG. 3 is a block diagram illustrating still another example of a display device according to one or more embodiments.

FIG. 4 is a circuit diagram illustrating an example of a pixel included in the display device of FIG. 1.

FIG. 5 is a cross-sectional view for describing a display panel included in the display device of FIG. 1.

FIG. 6 is a plan view for describing a display panel included in the display device of FIG. 1.

FIGS. 7 and 8 are layout diagrams for describing the display panel of FIG. 6.

FIG. 9 is a diagram for describing the display panel of FIG. 6.

FIG. 10 is a block diagram illustrating still another example of a display device according to one or more embodiments.

FIG. 11 is a view for describing a display panel included in the display device of FIG. 10.

FIG. 12 is a block diagram illustrating an electronic device according to one or more embodiments.

FIG. 13 is a schematic diagram illustrating various examples of the electronic device of FIG. 12.

### DETAILED DESCRIPTION

Hereinafter, example embodiments of the present disclosure will be explained in detail with reference to the accompanying drawings.

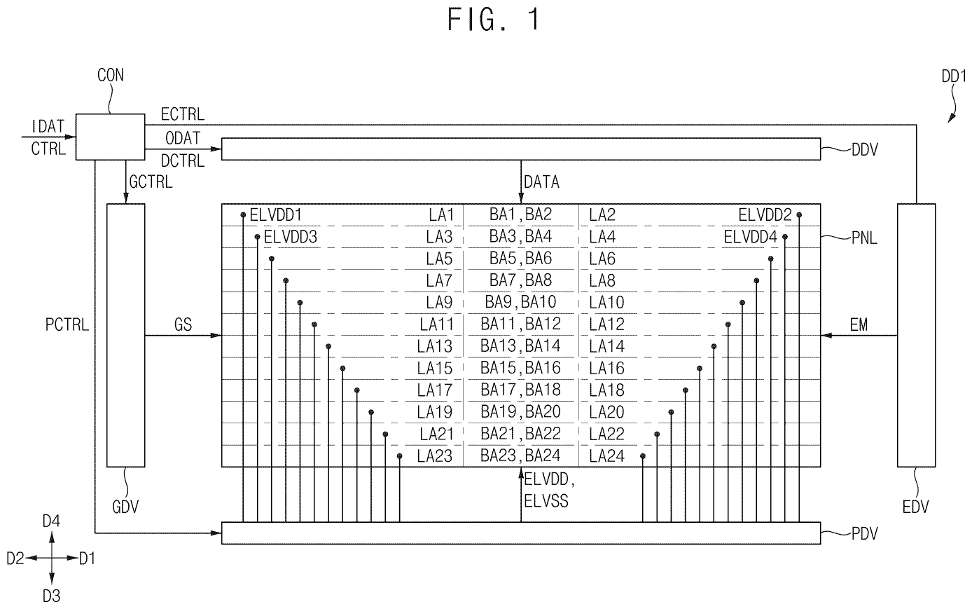

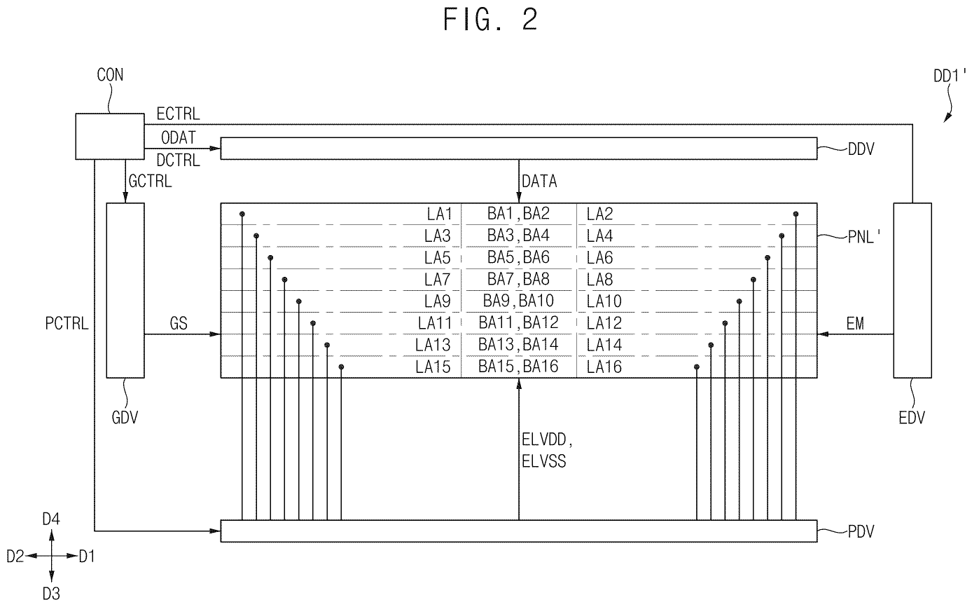

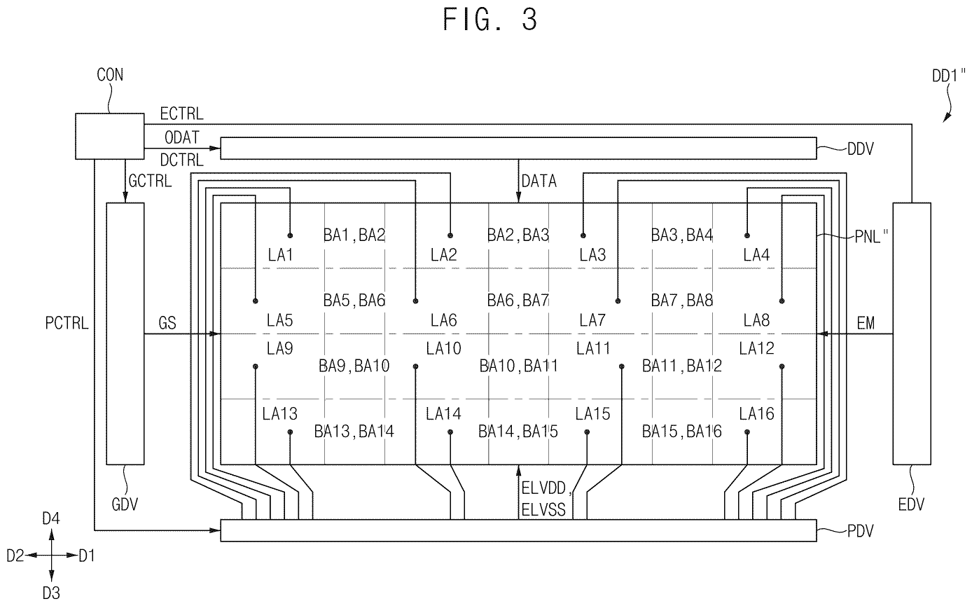

FIG. 1 is a block diagram illustrating an example of a display device according to one or more embodiments, FIG. 2 is a block diagram illustrating another example of a display device according to one or more embodiments, and FIG. 3 is a block diagram illustrating still another example of a display device according to one or more embodiments.

Referring to FIG. 1, a display device DD1 may include a display panel PNL, a data driving circuit (or referred to as a data driver) DDV, a gate driving circuit (or referred to as a gate driver) GDV, a light-emitting driving circuit (or referred to as a light-emitting driver) EDV, a power supply circuit (or referred to as a power supplier) PDV, and a timing control circuit (or referred to as a timing controller) CON.

The display panel PNL may be electrically connected to the data driving circuit DDV, the gate driving circuit GDV, the light-emitting driving circuit EDV, and the power supply circuit PDV. The display panel PNL may receive voltages and/or signals from the data driving circuit DDV, the gate driving circuit GDV, the light-emitting driving circuit EDV, and the power supply circuit PDV and may include at least one pixel. The at least one pixel may emit light, and thus the display panel PNL may display an image.

In an embodiment, the display panel PNL may include at least one region and at least one boundary region.

As illustrated in FIG. 1, the display panel PNL may include 24 regions. That is, the display panel PNL may include first to twenty-fourth regions LA1, LA2, LA3, LA4, LA5, LA6, LA7, LA8, LA9, LA10, LA11, LA12, LA13, LA14, LA15, LA16, LA17, LA18, LA19, LA20, LA21, LA22, LA23, and LA24.

In an embodiment, the second region LA2 may be adjacent to the first region LA1 in a first direction D1. The third region LA3 may be adjacent to the first region LA1 in a third direction D3 that intersects the first direction D1. The fourth region LA4 may be adjacent to the third region LA3 in the first direction D1.

In an embodiment, the display panel PNL may include 24 boundary regions. That is, the display panel PNL may include first to twenty-fourth boundary regions BA1, BA2, BA3, BA4, BA5, BA6, BA7, BA8, BA9, BA10, BA11, BA12, BA13, BA14, BA15, BA16, BA17, BA18, BA19, BA20, BA21, BA22, BA23, and BA24.

In an embodiment, the first and second boundary regions BA1 and BA2 may be disposed between the first region LA1 and the second region LA2. The third and fourth boundary regions BA3 and BA4 may be disposed between the third region LA3 and the fourth region LA4.

However, the present disclosure is not limited thereto. For example, a number and an arrangement of the regions may be appropriately determined. Accordingly, a number and an arrangement of the boundary regions may be determined based on the number and the arrangement of the regions.

In another embodiment, as illustrated in FIG. 2, a display device DD1′ may include a display panel PNL′, and the display panel PNL′ may include 16 regions. That is, the display panel PNL′ may include first to sixteenth regions LA1, LA2, LA3, LA4, LA5, LA6, LA7, LA8, LA9, LA10, LA11, LA12, LA13, LA14, LA15, and LA16.

Accordingly, the display panel PNL′ may include 16 boundary regions. That is, the display panel PNL′ may include first to sixteenth boundary regions BA1, BA2, BA3, BA4, BA5, BA6, BA7, BA8, BA9, BA10, BA11, BA12, BA13, BA14, BA15, and BA16.

In an embodiment, the power supply circuit PDV may include a plurality of multiplexers and may supply different voltages to respective regions. For example, a number of the multiplexers may be equal to the number of the regions, and each of the multiplexers may be implemented by a 3:1 multiplexer (MUX). Each of the multiplexers may receive first to third common voltages ELVSS_0, ELVSS_1, and ELVSS_2 and may supply one of the first to third common voltages ELVSS_0, ELVSS_1, and ELVSS_2 to a corresponding region.

In still another embodiment, as illustrated in FIG. 3, a display device DD1″ may include a display panel PNL″, and the display panel PNL″ may include 16 regions. That is, the display panel PNL″ may include first to sixteenth regions LA1, LA2, LA3, LA4, LA5, LA6, LA7, LA8, LA9, LA10, LA11, LA12, LA13, LA14, LA15, and LA16. The third region LA3 may be adjacent to the second region LA2 in the first direction D1, and the fifth region LA5 may be adjacent to the first region LA1 in the third direction D3.

Accordingly, the display panel PNL″ may include 16 boundary regions. That is, the display panel PNL″ may include first to sixteenth boundary regions BA1, BA2, BA3, BA4, BA5, BA6, BA7, BA8, BA9, BA10, BA11, BA12, BA13, BA14, BA15, and BA16. The first and second boundary regions BA1 and BA2 may be defined (or disposed) between the first region LA1 and the second region LA2. The second and third boundary regions BA2 and BA3 may be defined between the second region LA2 and the third region LA3.

Referring to FIG. 1 again, for example, signals and/or voltages provided to the respective regions may differ from one another.

In an embodiment, first to twenty-fourth power supply voltages may be provided to the first to twenty-fourth regions LA1, LA2, LA3, LA4, LA5, LA6, LA7, LA8, LA9, LA10, LA11, LA12, LA13, LA14, LA15, LA16, LA17, LA18, LA19, LA20, LA21, LA22, LA23, and LA24, respectively.

In this case, some of the first to twenty-fourth power supply voltages may be the same as each other, and some of the first to twenty-fourth power supply voltages may be different from each other.

For example, the first region LA1 may be provided with a first power supply voltage ELVDD1, the second region LA2 may be provided with a second power supply voltage ELVDD2, and the third region LA3 may be provided with a third power supply voltage ELVDD3. The first power supply voltage ELVDD1 and the second power supply voltage ELVDD2 may be the same as or different from each other, the second power supply voltage ELVDD2 and the third power supply voltage ELVDD3 may be the same as or different from each other, and the first power supply voltage ELVDD1 and the third power supply voltage ELVDD3 may be the same as or different from each other.

The data driving circuit DDV may receive output image data ODAT and a data control signal DCTRL from the timing control circuit CON and may generate a data voltage DATA.

The gate driving circuit GDV may receive a gate control signal GCTRL from the timing control circuit CON and may generate a gate signal GS.

The light-emitting driving circuit EDV may receive a light-emitting driving control signal ECTRL from the timing control circuit CON and may generate a light-emitting control signal EM.

The power supply circuit PDV may receive a power driving control signal PCTRL from the timing control circuit CON and may generate the power supply voltages ELVDD and a common voltage ELVSS.

The timing control circuit CON may receive a control signal CTRL and input image data IDAT from an external device and may control the data driving circuit DDV, the gate driving circuit GDV, the light-emitting driving circuit EDV, and the power supply circuit PDV.

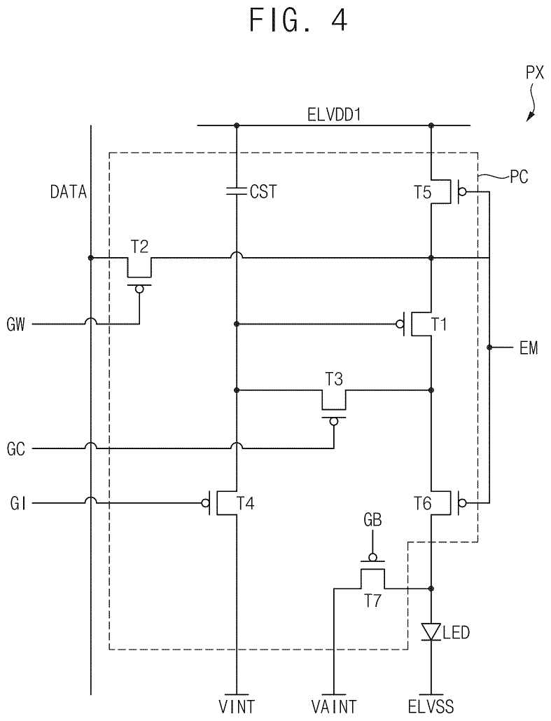

FIG. 4 is a circuit diagram illustrating an example of a pixel included in the display device of FIG. 1.

Referring to FIG. 4, the pixel PX included in the display device DD1 may include a pixel circuit PC and a light-emitting diode LED. The pixel circuit PC may generate a driving current and may be electrically connected to the light-emitting diode LED. The light-emitting diode LED may emit light corresponding to the driving current.

For example, the pixel PX may be a pixel disposed in the first region LA1, as an example. However, each of pixels disposed in the display panel PNL may have a circuit structure that is substantially similar to a circuit structure of the pixel PX described below.

In an embodiment, the pixel circuit PC may include a first transistor T1, a second transistor T2, a third transistor T3, a fourth transistor T4, a fifth transistor T5, a sixth transistor T6, a seventh transistor T7, and a storage capacitor CST.

The first transistor T1 may include a first terminal, a second terminal, and a gate terminal. The first terminal of the first transistor T1 may be connected to the second transistor T2. The second terminal of the first transistor T1 may be connected to the third transistor T3. The gate terminal of the first transistor T1 may be connected to the third transistor T3.

The first transistor T1 may generate the driving current based on a voltage difference between the first terminal of the first transistor T1 and the gate terminal of the first transistor T1.

The second transistor T2 may include a first terminal, a second terminal, and a gate terminal. The first terminal of the second transistor T2 may receive the data voltage DATA. The second terminal of the second transistor T2 may be connected to the first transistor T1. The gate terminal of the second transistor T2 may receive a first gate signal GW.

The second transistor T2 may transfer the data voltage DATA in response to the first gate signal GW.

The third transistor T3 may include a first terminal, a second terminal, and a gate terminal. The first terminal of the third transistor T3 may be connected to the second terminal of the first transistor T1. The second terminal of the third transistor T3 may be connected to the gate terminal of the first transistor T1. The gate terminal of the third transistor T3 may receive a second gate signal GC.

The third transistor T3 may compensate for a threshold voltage of the first transistor T1 in response to the second gate signal GC.

The fourth transistor T4 may include a first terminal, a second terminal, and a gate terminal. The first terminal of the fourth transistor T4 may receive a gate initialization voltage VINT. The second terminal of the fourth transistor T4 may be connected to the gate terminal of the first transistor T1. The gate terminal of the fourth transistor T4 may receive a third gate signal GI.

The fourth transistor T4 may initialize the gate terminal of the first transistor T1 in response to the third gate signal GI.

The fifth transistor T5 may include a first terminal, a second terminal, and a gate terminal. The first terminal of the fifth transistor T5 may receive the first power supply voltage ELVDD1. The second terminal of the fifth transistor T5 may be connected to the first transistor T1. The gate terminal of the fifth transistor T5 may receive the light-emitting control signal EM.

The fifth transistor T5 may supply the first power supply voltage ELVDD1 to the first transistor T1 in response to the light-emitting control signal EM.

The sixth transistor T6 may include a first terminal, a second terminal, and a gate terminal. The first terminal of the sixth transistor T6 may be connected to the first transistor T1. The second terminal of the sixth transistor T6 may be connected to the light-emitting diode LED. The gate terminal of the sixth transistor T6 may receive the light-emitting control signal EM.

The sixth transistor T6 may transfer the driving current from the first transistor T1 to the light-emitting diode LED in response to the light-emitting control signal EM.

The seventh transistor T7 may include a first terminal, a second terminal, and a gate terminal. The first terminal of the seventh transistor T7 may receive an anode initialization voltage VAINT. The second terminal of the seventh transistor T7 may be connected to the light-emitting diode LED. The gate terminal of the seventh transistor T7 may receive a fourth gate signal GB.

The seventh transistor T7 may transfer the anode initialization voltage VAINT to the light-emitting diode LED in response to the fourth gate signal GB.

The storage capacitor CST may include a first terminal and a second terminal. The first terminal of the storage capacitor CST may receive the first power supply voltage ELVDD1. The second terminal of the storage capacitor CST may be connected to the first transistor T1. The storage capacitor CST may store a voltage corresponding to the data voltage DATA.

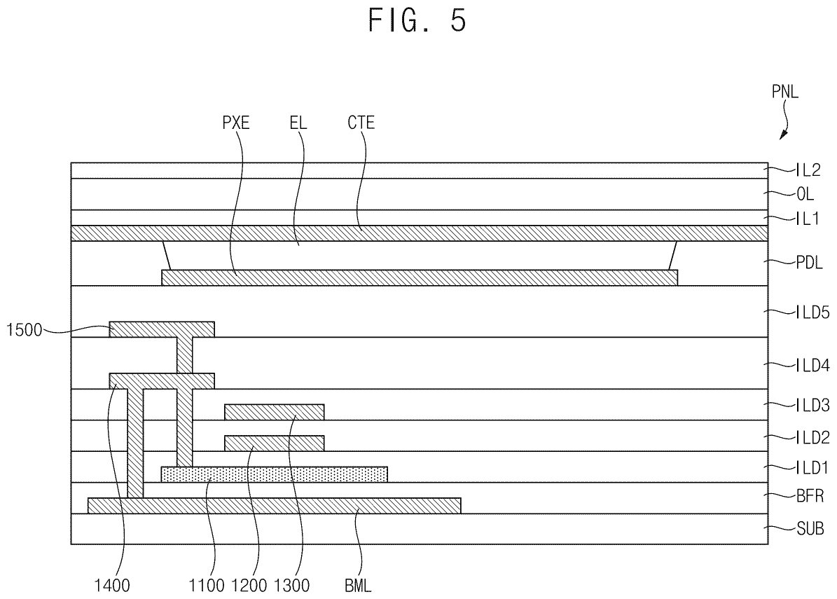

FIG. 5 is a cross-sectional view for describing a display panel included in the display device of FIG. 1.

Referring to FIG. 5, the display panel PNL may include a substrate SUB, a lower conductive layer BML, a buffer layer BFR, an active pattern 1100, a first insulating layer ILD1, a first conductive layer 1200, a second insulating layer ILD2, a second conductive layer 1300, a third insulating layer ILD3, a third conductive layer 1400, a fourth insulating layer ILD4, a fourth conductive layer 1500, a fifth insulating layer ILD5, a pixel electrode PXE, a pixel definition layer PDL, a light-emitting layer EL, a common electrode CTE, a first inorganic layer IL1, an organic layer OL, and a second inorganic layer IL2.

The substrate SUB may include a transparent or opaque material. In an embodiment, non-limiting examples of materials usable for the substrate SUB may include glass, quartz, plastic, and/or the like. For example but not limited to, when the substrate SUB includes plastic, the substrate SUB may include at least one of polyimide, polyethersulfone, polyacrylate, polyetherimide, polyethylene naphthalate, polyethylene terephthalate, polyphenylene sulfide, polyarylate, polycarbonate, and cellulose acetate propionate. These materials may be used alone or in combination. In addition, the substrate SUB may have a single-layer structure or a multi-layer structure.

The lower conductive layer BML may be disposed on the substrate SUB. In an embodiment, the lower conductive layer BML may include, for example but not limited to, metals, alloys, metal oxides, metal nitrides, and/or the like.

For example but not limited to, the lower conductive layer BML may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These materials may be used alone or in combination. In addition, the lower conductive layer BML may have a single-layer structure or a multi-layer structure.

The buffer layer BFR may cover the lower conductive layer BML and may be disposed on the substrate SUB. In an embodiment, the buffer layer BFR may include an insulating material. For example but not limited to, the buffer layer BFR may include silicon oxide, silicon nitride, titanium oxide, tantalum oxide, and/or the like. These materials may be used alone or in combination. In addition, the buffer layer BFR may have a single-layer structure or a multi-layer structure.

The active pattern 1100 may be disposed on the buffer layer BFR. In an embodiment, the active pattern 1100 may include a silicon semiconductor, an oxide semiconductor, and/or the like. For example but not limited to, the silicon semiconductor may include amorphous silicon, polycrystalline silicon, and/or the like. The active pattern 1100 may allow or block current flow according to a gate signal provided to the first conductive layer 1200.

The first insulating layer ILD1 may cover the active pattern 1100 and may be disposed on the buffer layer BFR. In an embodiment, the first insulating layer ILD1 may include an insulating material. For example but not limited to, the first insulating layer ILD1 may include silicon oxide, silicon nitride, titanium oxide, tantalum oxide, and/or the like. These materials may be used alone or in combination. In addition, the first insulating layer ILD1 may have a single-layer structure or a multi-layer structure.

The first conductive layer 1200 may be disposed on the first insulating layer ILD1 and may overlap with the active pattern 1100. In an embodiment, the first conductive layer 1200 may include metals, alloys, metal oxides, metal nitrides, and/or the like.

For example but not limited to, the first conductive layer 1200 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These materials may be used alone or in combination. In addition, the first conductive layer 1200 may have a single-layer structure or a multi-layer structure.

The second insulating layer ILD2 may cover the first conductive layer 1200 and may be disposed on the first insulating layer ILD1. In an embodiment, the second insulating layer ILD2 may include an insulating material. For example but not limited to, the second insulating layer ILD2 may include silicon oxide, silicon nitride, titanium oxide, tantalum oxide, and/or the like. These materials may be used alone or in combination. In addition, the second insulating layer ILD2 may have a single-layer structure or a multi-layer structure.

The second conductive layer 1300 may be disposed on the second insulating layer ILD2 and may overlap with the first conductive layer 1200. In an embodiment, the second conductive layer 1300 may include metals, alloys, metal oxides, metal nitrides, and/or the like.

For example but not limited to, the second conductive layer 1300 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These materials may be used alone or in combination. In addition, the second conductive layer 1300 may have a single-layer structure or a multi-layer structure.

The third insulating layer ILD3 may cover the second conductive layer 1300 and may be disposed on the second insulating layer ILD2. In an embodiment, the third insulating layer ILD3 may include an insulating material. For example but not limited to, the third insulating layer ILD3 may include silicon oxide, silicon nitride, titanium oxide, tantalum oxide, and/or the like. These materials may be used alone or in combination. In addition, the third insulating layer ILD3 may have a single-layer structure or a multi-layer structure.

The third conductive layer 1400 may be disposed on the third insulating layer ILD3 and may be in contact with the active pattern 1100 and the lower conductive layer BML. In an embodiment, the third conductive layer 1400 may include metals, alloys, metal oxides, metal nitrides, and/or the like.

For example but not limited to, the third conductive layer 1400 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These materials may be used alone or in combination. In addition, the third conductive layer 1400 may have a single-layer structure or a multi-layer structure.

The fourth insulating layer ILD4 may cover the third conductive layer 1400 and may be disposed on the third insulating layer ILD3. In an embodiment, the fourth insulating layer ILD4 may include an insulating material. For example but not limited to, the fourth insulating layer ILD4 may include an organic insulating material such as photoresist, polyacryl-based resin, polyimide-based resin, acrylic resin, and/or the like. These materials may be used alone or in combination. In addition, the fourth insulating layer ILD4 may have a single-layer structure or a multi-layer structure.

The fourth conductive layer 1500 may be disposed on the fourth insulating layer ILD4 and may be in contact with the third conductive layer 1400. In an embodiment, the fourth conductive layer 1500 may include metals, alloys, metal oxides, metal nitrides, and/or the like.

For example but not limited to, the fourth conductive layer 1500 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These materials may be used alone or in combination. In addition, the fourth conductive layer 1500 may have a single-layer structure or a multi-layer structure.

The fifth insulating layer ILD5 may cover the fourth conductive layer 1500 and may be disposed on the fourth insulating layer ILD4. In an embodiment, the fifth insulating layer ILD5 may include an insulating material. For example but not limited to, the fifth insulating layer ILD5 may include an organic insulating material such as photoresist, polyacryl-based resin, polyimide-based resin, acrylic resin, and/or the like. These materials may be used alone or in combination. In addition, the fifth insulating layer ILD5 may have a single-layer structure or a multi-layer structure.

The pixel electrode PXE may be disposed on the fifth insulating layer ILD5. In an embodiment, the pixel electrode PXE may include metals, alloys, metal oxides, metal nitrides, and/or the like.

For example but not limited to, the pixel electrode PXE may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These materials may be used alone or in combination. In addition, the pixel electrode PXE may have a single-layer structure or a multi-layer structure.

In an embodiment, the pixel definition layer PDL may be disposed on the fifth insulating layer ILD5, and an opening that exposes the pixel electrode PXE may be formed in the pixel definition layer PDL.

For example but not limited to, the pixel definition layer PDL may include an organic material such as polyimide-based resin (e.g., a photosensitive polyimide-based resin (PSPI)), photoresist, polyacryl-based resin, acrylic resin, and/or the like or may include an inorganic material such as silicon oxide, silicon nitride, and/or the like.

The light-emitting layer EL may be disposed on the pixel electrode PXE. In an embodiment, the light-emitting layer EL may have a multi-layer structure including an organic light-emitting layer, a hole injection layer, a hole transport layer, an electron transport layer, an electron injection layer, and the like.

The common electrode CTE may be disposed on the light-emitting layer EL. In an embodiment, the common electrode CTE may include metals, alloys, metal oxides, metal nitrides, and/or the like.

In an embodiment, the common electrode CTE may include metals, alloys, conductive metal oxides, and/or the like. For example, but not limited to the common electrode CTE may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These materials may be used alone or in combination.

The first inorganic layer IL1 may be disposed on the common electrode CTE and may include an inorganic material.

The organic layer OL may be disposed on the first inorganic layer IL1 and may include an organic material.

The second inorganic layer IL2 may be disposed on the organic layer OL and may include an inorganic material.

The first inorganic layer IL1, the organic layer OL, and the second inorganic layer IL2 may serve as an encapsulation layer to protect the light-emitting layer EL from the penetration of moisture and/or oxygen.

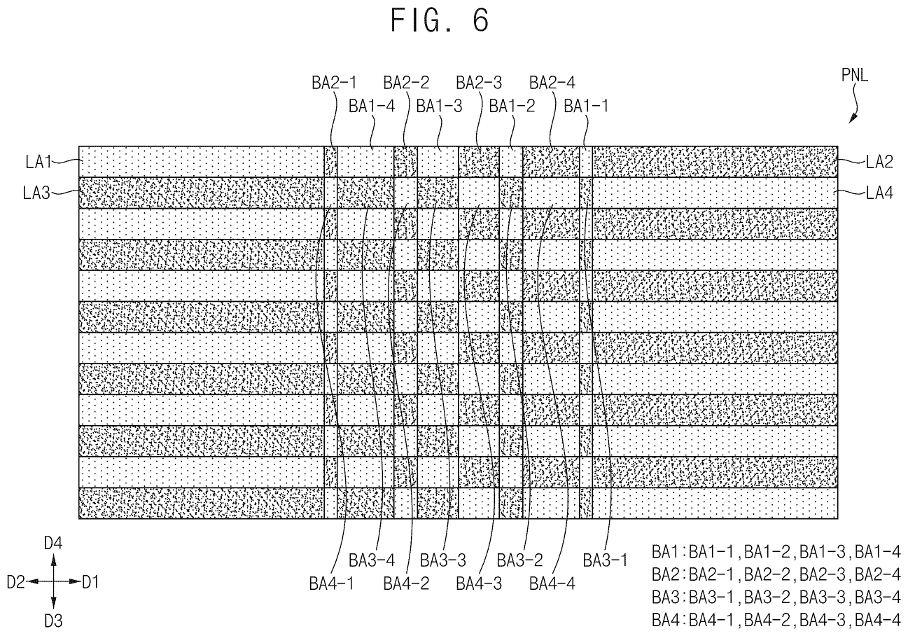

FIG. 6 is a plan view for describing a display panel included in the display device of FIG. 1.

Referring to FIG. 6, as described above, the display panel PNL may include a plurality of regions and a plurality of boundary regions. For example, the display panel PNL may include the first region LA1, the second region LA2, the first boundary regions BA1, the second boundary regions BA2, the third region LA3, the fourth region LA4, the third boundary regions BA3, and the fourth boundary regions BA4.

In an embodiment, the first boundary regions BA1 may include a plurality of boundary regions. For example, the first boundary regions BA1 may include a first-first boundary region BA1-1, a first-second boundary region BA1-2, a first-third boundary region BA1-3, and a first-fourth boundary region BA1-4.

In an embodiment, the second boundary regions BA2 may include a plurality of boundary regions. For example, the second boundary regions BA2 may include a second-first boundary region BA2-1, a second-second boundary region BA2-2, a second-third boundary region BA2-3, and a second-fourth boundary region BA2-4.

In an embodiment, the second region LA2 may be adjacent to the first region LA1 in the first direction D1. The first boundary regions BA1 may be disposed between the first region LA1 and the second region LA2, and the second boundary regions BA2 may be disposed between the first region LA1 and the second region LA2.

In an embodiment, the first-first boundary region BA1-1, the first-second boundary region BA1-2, the first-third boundary region BA1-3, and the first-fourth boundary region BA1-4 may be arranged in order in a second direction D2 opposite to the first direction D1.

In other words, the first-first boundary region BA1-1 may be disposed between the first region LA1 and the second region LA2, the first-second boundary region BA1-2 may be disposed between the first-first boundary region BA1-1 and the first region LA1, the first-third boundary region BA1-3 may be disposed between the first-second boundary region BA1-2 and the first region LA1, and the first-fourth boundary region BA1-4 may be disposed between the first-third boundary region BA1-3 and the first region LA1.

In an embodiment, the second-first boundary region BA2-1, the second-second boundary region BA2-2, the second-third boundary region BA2-3, and the second-fourth boundary region BA2-4 may be arranged in order in the first direction D1.

In other words, the second-first boundary region BA2-1 may be disposed between the first region LA1 and the second region LA2, the second-second boundary region BA2-2 may be disposed between the second-first boundary region BA2-1 and the second region LA2, the second-third boundary region BA2-3 may be disposed between the second-second boundary region BA2-2 and the second region LA2, and the second-fourth boundary region BA2-4 may be disposed between the second-third boundary region BA2-3 and the second region LA2.

In an embodiment, the first-first boundary region BA1-1, the first-second boundary region BA1-2, the first-third boundary region BA1-3, the first-fourth boundary region BA1-4, the second-first boundary region BA2-1, the second-second boundary region BA2-2, the second-third boundary region BA2-3, and the second-fourth boundary region BA2-4 may be arranged alternately with each other.

In other words, the first-first boundary region BA1-1 may be disposed between the second region LA2 and the second-fourth boundary region BA2-4, the first-second boundary region BA1-2 may be disposed between the second-fourth boundary region BA2-4 and the second-third boundary region BA2-3, the first-third boundary region BA1-3 may be disposed between the second-third boundary region BA2-3 and the second-second boundary region BA2-2, and the first-fourth boundary region BA1-4 may be disposed between the second-second boundary region BA2-2 and the second-first boundary region BA2-1.

In an embodiment, the first power supply voltage ELVDD1 may be provided to the first region LA1. That is, pixels disposed in the first region LA1 may be provided with the first power supply voltage ELVDD1.

In an embodiment, the second power supply voltage ELVDD2 may be provided to the second region LA2. That is, pixels disposed in the second region LA2 may be provided with the second power supply voltage ELVDD2. For example, the second power supply voltage ELVDD2 may be different from the first power supply voltage ELVDD1.

In an embodiment, the first power supply voltage ELVDD1 may be provided to the first boundary regions BA1. For example, the first power supply voltage ELVDD1 may be provided to the first-first boundary region BA1-1, the first-second boundary region BA1-2, the first-third boundary region BA1-3, and the first-fourth boundary region BA1-4. That is, pixels disposed in the first-first boundary region BA1-1, the first-second boundary region BA1-2, the first-third boundary region BA1-3, and the first-fourth boundary region BA1-4 may be provided with the first power supply voltage ELVDD1.

In an embodiment, the second power supply voltage ELVDD2 may be provided to the second boundary regions BA2. For example, the second power supply voltage ELVDD2 may be provided to the second-first boundary region BA2-1, the second-second boundary region BA2-2, the second-third boundary region BA2-3, and the second-fourth boundary region BA2-4. That is, pixels disposed in the second-first boundary region BA2-1, the second-second boundary region BA2-2, the second-third boundary region BA2-3, and the second-fourth boundary region BA2-4 may be provided with the second power supply voltage ELVDD2.

In an embodiment, each area of the first boundary regions BA1 may gradually increase in a direction from the second region LA2 to the first region LA1. That is, each area of the first boundary regions BA1 may gradually increase in the second direction D2.

For example, an area of the first-second boundary region BA1-2 may be larger than an area of the first-first boundary region BA1-1. That is, a number of pixels disposed in the first-second boundary region BA1-2 may be greater than a number of the pixels disposed in the first-first boundary region BA1-1.

For example, an area of the first-third boundary region BA1-3 may be larger than the area of the first-second boundary region BA1-2. That is, a number of pixels disposed in the first-third boundary region BA1-3 may be greater than the number of the pixels disposed in the first-second boundary region BA1-2.

For example, an area of the first-fourth boundary region BA1-4 may be larger than the area of the first-third boundary region BA1-3. That is, a number of pixels disposed in the first-fourth boundary region BA1-4 may be greater than the number of the pixels disposed in the first-third boundary region BA1-3.

In addition, an area of the first region LA1 may be larger than the area of the first-fourth boundary region BA1-4. That is, a number of the pixels disposed in the first region LA1 may be greater than the number of the pixels disposed in the first-fourth boundary region BA1-4.

In an embodiment, each area of the second boundary regions BA2 may gradually increase in a direction from the first region LA1 to the second region LA2. That is, each area of the second boundary regions BA2 may gradually increase in the first direction D1.

For example, an area of the second-second boundary region BA2-2 may be larger than an area of the second-first boundary region BA2-1. That is, a number of pixels disposed in the second-second boundary region BA2-2 may be greater than a number of a pixels disposed in the second-first boundary region BA2-1.

For example, an area of the second-third boundary region BA2-3 may be larger than the area of the second-second boundary region BA2-2. That is, a number of pixels disposed in the second-third boundary region BA2-3 may be greater than the number of the pixels disposed in the second-second boundary region BA2-2.

For example, an area of the second-fourth boundary region BA2-4 may be larger than the area of the second-third boundary region BA2-3. That is, a number of pixels disposed in the second-fourth boundary region BA2-4 may be greater than the number of the pixels disposed in the second-third boundary region BA2-3.

In addition, an area of the second region LA2 may be larger than the area of the second-fourth boundary region BA2-4. That is, a number of the pixels disposed in the second region LA2 may be greater than the number of the pixels disposed in the second-fourth boundary region BA2-4.

In an embodiment, the area of the first region LA1 may be substantially equal to the area of the second region LA2.

In addition, the area of the first-first boundary region BA1-1 may be substantially equal to the area of the second-first boundary region BA2-1, the area of the first-second boundary region BA1-2 may be substantially equal to the area of the second-second boundary region BA2-2, the area of the first-third boundary region BA1-3 may be substantially equal to the area of the second-third boundary region BA2-3, and the area of the first-fourth boundary region BA1-4 may be substantially equal to the area of the second-fourth boundary region BA2-4.

In an embodiment, the third boundary regions BA3 may include a plurality of boundary regions. For example, the third boundary regions BA3 may include a third-first boundary region BA3-1, a third-second boundary region BA3-2, a third-third boundary region BA3-3, and a third-fourth boundary region BA3-4.

In an embodiment, the fourth boundary regions BA4 may include a plurality of boundary regions. For example, the fourth boundary regions BA4 may include a fourth-first boundary region BA4-1, a fourth-second boundary region BA4-2, a fourth-third boundary region BA4-3, and a fourth-fourth boundary region BA4-4.

In an embodiment, the fourth region LA4 may be adjacent to the third region LA3 in the first direction D1. The third boundary regions BA3 may be disposed between the third region LA3 and the fourth region LA4, and the fourth boundary regions BA4 may be disposed between the third region LA3 and the fourth region LA4.

In an embodiment, the third-first boundary region BA3-1, the third-second boundary region BA3-2, the third-third boundary region BA3-3, and the third-fourth boundary region BA3-4 may be arranged in order in the second direction D2 opposite to the first direction D1.

In other words, the third-first boundary region BA3-1 may be disposed between the third region LA3 and the fourth region LA4, the third-second boundary region BA3-2 may be disposed between the third-first boundary region BA3-1 and the third region LA3, the third-third boundary region BA3-3 may be disposed between the third-second boundary region BA3-2 and the third region LA3, and the third-fourth boundary region BA3-4 may be disposed between the third-third boundary region BA3-3 and the third region LA3.

In an embodiment, the fourth-first boundary region BA4-1, the fourth-second boundary region BA4-2, the fourth-third boundary region BA4-3, and the fourth-fourth boundary region BA4-4 may be arranged in order in the first direction D1.

In other words, the fourth-first boundary region BA4-1 may be disposed between the third region LA3 and the fourth region LA4, the fourth-second boundary region BA4-2 may be disposed between the fourth-first boundary region BA4-1 and the fourth region LA4, the fourth-third boundary region BA4-3 may be disposed between the fourth-second boundary region BA4-2 and the fourth region LA4, and the fourth-fourth boundary region BA4-4 may be disposed between the fourth-third boundary region BA4-3 and the fourth region LA4.

In an embodiment, the third-first boundary region BA3-1, the third-second boundary region BA3-2, the third-third boundary region BA3-3, the third-fourth boundary region BA3-4, the fourth-first boundary region BA4-1, the fourth-second boundary region BA4-2, the fourth-third boundary region BA4-3, and the fourth-fourth boundary region BA4-4 may be arranged alternately with each other.

In other words, the third-first boundary region BA3-1 may be disposed between the fourth region LA4 and the fourth-fourth boundary region BA4-4, the third-second boundary region BA3-2 may be disposed between the fourth-fourth boundary region BA4-4 and the fourth-third boundary region BA4-3, the third-third boundary region BA3-3 may be disposed between the fourth-third boundary region BA4-3 and the fourth-second boundary region BA4-2, and the third-fourth boundary region BA3-4 may be disposed between the fourth-second boundary region BA4-2 and the fourth-first boundary region BA4-1.

In an embodiment, the third power supply voltage ELVDD3 may be provided to the third region LA3. That is, pixels disposed in the third region LA3 may be provided with the third power supply voltage ELVDD3. In an embodiment, the third power supply voltage ELVDD3 may be different from the first and second power supply voltages ELVDD1 and ELVDD2. In another embodiment, the third power supply voltage ELVDD3 may be the same as at least one of the first and second power supply voltages ELVDD1 and ELVDD2.

In an embodiment, the fourth power supply voltage ELVDD4 may be provided to the fourth region LA4. That is, pixels disposed in the fourth region LA4 may be provided with the fourth power supply voltage ELVDD4. For example, the fourth power supply voltage ELVDD4 may be different from the third power supply voltage ELVDD3.

In an embodiment, the third power supply voltage ELVDD3 may be provided to the third boundary regions BA3. For example, the third power supply voltage ELVDD3 may be provided to the third-first boundary region BA3-1, the third-second boundary region BA3-2, the third-third boundary region BA3-3, and the third-fourth boundary region BA3-4. That is, pixels disposed in the third-first boundary region BA3-1, the third-second boundary region BA3-2, the third-third boundary region BA3-3, and the third-fourth boundary region BA3-4 may be provided with the third power supply voltage ELVDD3.

In an embodiment, the fourth power supply voltage ELVDD4 may be provided to the fourth boundary regions BA4. For example, the fourth power supply voltage ELVDD4 may be provided to the fourth-first boundary region BA4-1, the fourth-second boundary region BA4-2, the fourth-third boundary region BA4-3, and the fourth-fourth boundary region BA4-4. That is, pixels disposed in the fourth-first boundary region BA4-1, the fourth-second boundary region BA4-2, the fourth-third boundary region BA4-3, and the fourth-fourth boundary region BA4-4 may be provided with the fourth power supply voltage ELVDD4.

In an embodiment, each area of the third boundary regions BA3 may gradually increase in a direction from the fourth region LA4 to the third region LA3. That is, each area of the third boundary regions BA3 may gradually increase in the second direction D2.

For example, an area of the third-second boundary region BA3-2 may be larger than an area of the third-first boundary region BA3-1. That is, a number of pixels disposed in the third-second boundary region BA3-2 may be greater than a number of pixels disposed in the third-first boundary region BA3-1.

For example, an area of the third-third boundary region BA3-3 may be larger than the area of the third-second boundary region BA3-2. That is, a number of pixels disposed in the third-third boundary region BA3-3 may be greater than the number of the pixels disposed in the third-second boundary region BA3-2.

For example, an area of the third-fourth boundary region BA3-4 may be larger than the area of the third-third boundary region BA3-3. That is, a number of pixels disposed in the third-fourth boundary region BA3-4 may be greater than the number of the pixels disposed in the third-third boundary region BA3-3.

In addition, an area of the third region LA3 may be larger than the area of the third-fourth boundary region BA3-4. That is, a number of the pixels disposed in the third region LA3 may be greater than the number of the pixels disposed in the third-fourth boundary region BA3-4.

In an embodiment, each area of the fourth boundary regions BA4 may gradually increase in a direction from the third region LA3 to the fourth region LA4. That is, each area of the fourth boundary regions BA4 may gradually increase in the first direction D1.

For example, an area of the fourth-second boundary region BA4-2 may be larger than an area of the fourth-first boundary region BA4-1. That is, a number of pixels disposed in the fourth-second boundary region BA4-2 may be greater than a number of pixels disposed in the fourth-first boundary region BA4-1.

For example, an area of the fourth-third boundary region BA4-3 may be larger than the area of the fourth-second boundary region BA4-2. That is, a number of pixels disposed in the fourth-third boundary region BA4-3 may be greater than the number of the pixels disposed in the fourth-second boundary region BA4-2.

For example, an area of the fourth-fourth boundary region BA4-4 may be larger than the area of the fourth-third boundary region BA4-3. That is, a number of pixels disposed in the fourth-fourth boundary region BA4-4 may be greater than the number of the pixels disposed in the fourth-third boundary region BA4-3.

In addition, an area of the fourth region LA4 may be larger than the area of the fourth-fourth boundary region BA4-4. That is, a number of the pixels disposed in the fourth region LA4 may be greater than the number of the pixels disposed in the fourth-fourth boundary region BA4-4.

In an embodiment, the area of the third region LA3 may be substantially equal to the area of the fourth region LA4.

In addition, the area of the third-first boundary region BA3-1 may be substantially equal to the area of the fourth-first boundary region BA4-1, the area of the third-second boundary region BA3-2 may be substantially equal to the area of the fourth-second boundary region BA4-2, the area of the third-third boundary region BA3-3 may be substantially equal to the area of the fourth-third boundary region BA4-3, and the area of the third-fourth boundary region BA3-4 may be substantially equal to the area of the fourth-fourth boundary region BA4-4.

In an embodiment, the area of the third-first boundary region BA3-1 may be substantially equal to the area of the first-first boundary region BA1-1, the area of the third-second boundary region BA3-2 may be substantially equal to the area of the first-second boundary region BA1-2, the area of the third-third boundary region BA3-3 may be substantially equal to the area of the first-third boundary region BA1-3, and the area of the third-fourth boundary region BA3-4 may be substantially equal to the area of the first-fourth boundary region BA1-4.

In an embodiment, the area of the fourth-first boundary region BA4-1 may be substantially equal to the area of the second-first boundary region BA2-1, the area of the fourth-second boundary region BA4-2 may be substantially equal to the area of the second-second boundary region BA2-2, the area of the fourth-third boundary region BA4-3 may be substantially equal to the area of the second-third boundary region BA2-3, and the area of the fourth-fourth boundary region BA4-4 may be substantially equal to the area of the second-fourth boundary region BA2-4.

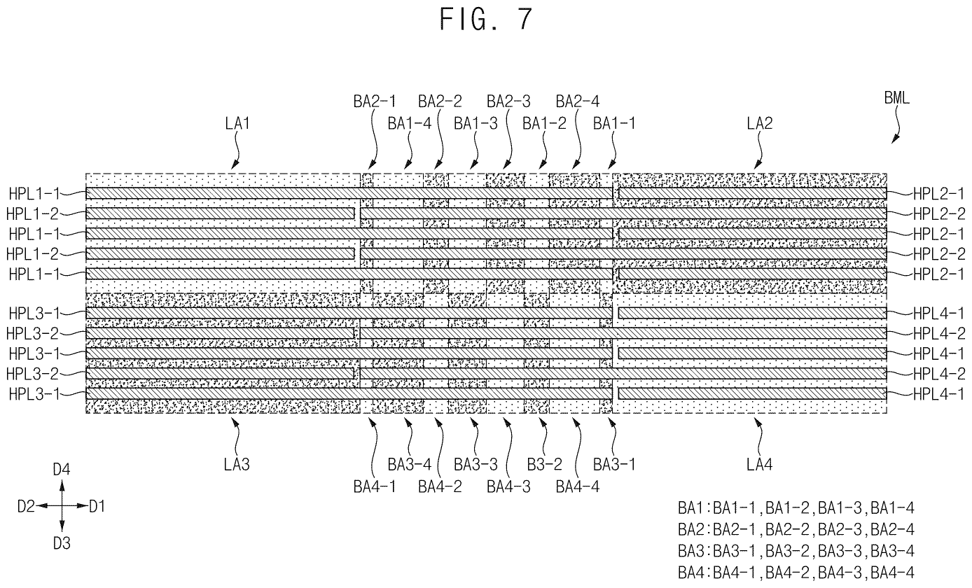

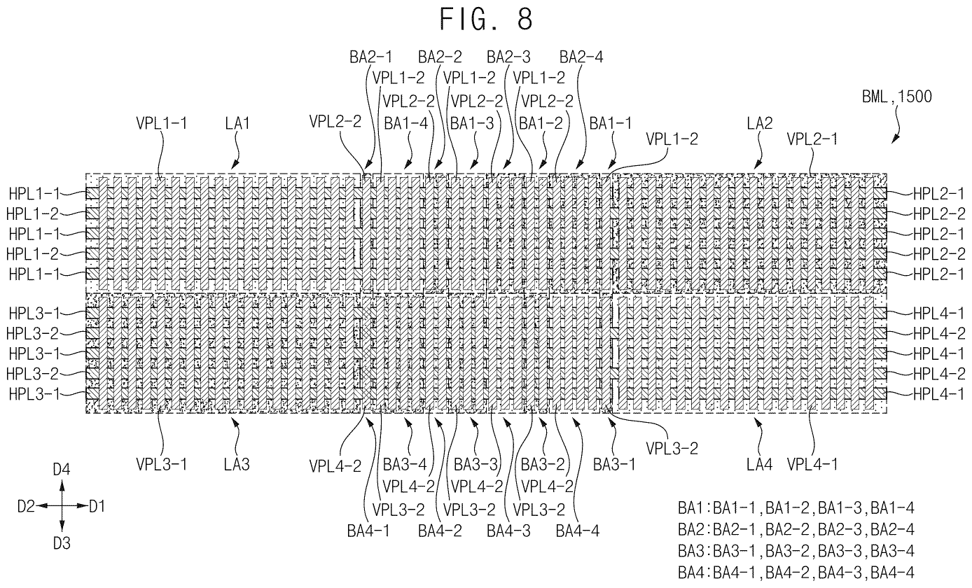

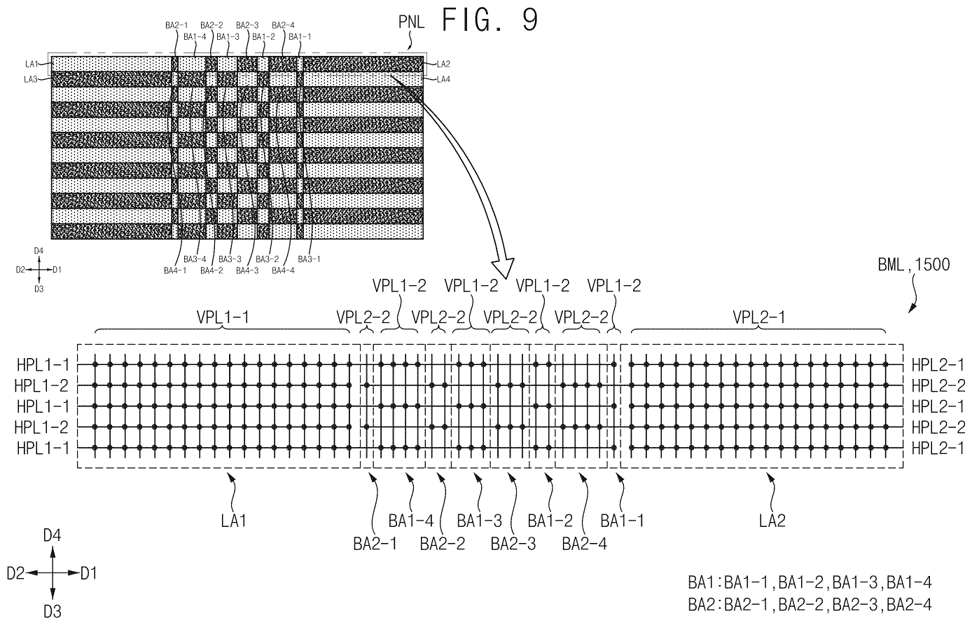

FIGS. 7 and 8 are layout diagrams for describing the display panel of FIG. 6, and FIG. 9 is a diagram for describing the display panel of FIG. 6.

For example, FIG. 7 is a layout diagram for describing power supply voltage horizontal wirings disposed on the same layer as the lower conductive layer BML included in the display panel of FIG. 6. FIG. 8 is a layout diagram for describing power supply voltage vertical wirings disposed on the same layer as the fourth conductive layer 1500 included in the display panel of FIG. 6. FIG. 9 is a diagram for describing an electrical connection relationship between the power supply voltage horizontal wirings and the power supply voltage vertical wirings.

Referring to FIG. 7, the display panel PNL may further include at least one power supply voltage horizontal wiring. In an embodiment, the power supply voltage horizontal wiring may be disposed on the same layer as the lower conductive layer BML. For example, the power supply voltage horizontal wiring may be disposed on the substrate SUB.

However, the present disclosure is not limited thereto. In another embodiment, the power supply voltage horizontal wiring may be disposed on the same layer as the third conductive layer 1400. For example, the power supply voltage horizontal wiring may be disposed on the third insulating layer ILD3.

In an embodiment, as illustrated in FIG. 7, the display panel PNL may include first-first power supply voltage horizontal wirings HPL1-1, first-second power supply voltage horizontal wirings HPL1-2, second-first power supply voltage horizontal wirings HPL2-1, second-second power supply voltage horizontal wirings HPL2-2, third-first power supply voltage horizontal wirings HPL3-1, third-second power supply voltage horizontal wirings HPL3-2, fourth-first power supply voltage horizontal wirings HPL4-1, and fourth-second power supply voltage horizontal wirings HPL4-2.

Each of the first-first power supply voltage horizontal wirings HPL1-1 and each of the first-second power supply voltage horizontal wirings HPL1-2 may be referred to as a first power supply voltage horizontal wiring. Each of the second-first power supply voltage horizontal wirings HPL2-1 and each of the second-second power supply voltage horizontal wirings HPL2-2 may be referred to as second power supply voltage horizontal wiring. Each of the third-first power supply voltage horizontal wirings HPL3-1 and each of the third-second power supply voltage horizontal wirings HPL3-2 may be referred to as a third power supply voltage horizontal wiring. Each of the fourth-first power supply voltage horizontal wirings HPL4-1 and each of the fourth-second power supply voltage horizontal wirings HPL4-2 may be referred to as a fourth power supply voltage horizontal wiring.

In an embodiment, the first-first power supply voltage horizontal wirings HPL1-1 may extend in the first direction D1 (e.g., a row direction) and may overlap with the first region LA1, the first boundary regions BA1, and the second boundary regions BA2.

In an embodiment, the first-second power supply voltage horizontal wirings HPL1-2 may extend in the first direction D1 and may overlap with the first region LA1.

In an embodiment, the first-first power supply voltage horizontal wirings HPL1-1 and the first-second power supply voltage horizontal wirings HPL1-2 may be alternately arranged in the third direction D3 (e.g., a column direction) in the first region LA1.

In an embodiment, the first-first power supply voltage horizontal wirings HPL1-1 and the first-second power supply voltage horizontal wirings HPL1-2 may be provided with the first power supply voltage ELVDD1.

In an embodiment, the second-first power supply voltage horizontal wirings HPL2-1 may extend in the second direction D2 (e.g., the row direction) and may overlap with the second region LA2.

In an embodiment, the second-second power supply voltage horizontal wirings HPL2-2 may extend in the second direction D2 and may overlap with the second region LA2, the first boundary regions BA1, and the second boundary regions BA2.

In an embodiment, the second-first power supply voltage horizontal wirings HPL2-1 and the second-second power supply voltage horizontal wirings HPL2-2 may be alternately arranged in the third direction D3 (e.g., the column direction) in the second region LA2.

In an embodiment, the second-first power supply voltage horizontal wirings HPL2-1 and the second-second power supply voltage horizontal wirings HPL2-2 may be provided with the second power supply voltage ELVDD2.

In an embodiment, the first-first power supply voltage horizontal wirings HPL1-1 and the second-second power supply voltage horizontal wirings HPL2-2 may be alternately arranged in the third direction D3 in the first boundary regions BA1 and the second boundary regions BA2.

In an embodiment, as illustrated in FIG. 7, each of the first-first power supply voltage horizontal wirings HPL1-1 may be disconnected from each of the second-first power supply voltage horizontal wirings HPL2-1.

In an embodiment, as illustrated in FIG. 7, each of the first-second power supply voltage horizontal wirings HPL1-2 may be disconnected from each of the second-second power supply voltage horizontal wirings HPL2-2.

In an embodiment, the third-first power supply voltage horizontal wirings HPL3-1 may extend in the first direction D1 and may overlap with the third region LA3, the third boundary regions BA3, and the fourth boundary regions BA4.

In an embodiment, the third-second power supply voltage horizontal wirings HPL3-2 may extend in the first direction D1 and may overlap with the third region LA3.

In an embodiment, the third-first power supply voltage horizontal wirings HPL3-1 and the third-second power supply voltage horizontal wirings HPL3-2 may be alternately arranged in the third direction D3 in the third region LA3.

In an embodiment, the third-first power supply voltage horizontal wirings HPL3-1 and the third-second power supply voltage horizontal wirings HPL3-2 may be provided with the third power supply voltage ELVDD3.

In an embodiment, the fourth-first power supply voltage horizontal wirings HPL4-1 may extend in the second direction D2 and may overlap with the fourth region LA4.

In an embodiment, the fourth-second power supply voltage horizontal wirings HPL4-2 may extend in the second direction D2 and may overlap with the fourth region LA4, the third boundary regions BA3, and the fourth boundary regions BA4.

In an embodiment, the fourth-first power supply voltage horizontal wirings HPL4-1 and the fourth-second power supply voltage horizontal wirings HPL4-2 may be alternately arranged in the third direction D3 in the fourth region LA4.

In an embodiment, the fourth-first power supply voltage horizontal wirings HPL4-1 and the fourth-second power supply voltage horizontal wirings HPL4-2 may be provided with the fourth power supply voltage ELVDD4.

In an embodiment, the third-first power supply voltage horizontal wirings HPL3-1 and the fourth-second power supply voltage horizontal wirings HPL4-2 may be alternately arranged in the third direction D3 in the third boundary regions BA3 and the fourth boundary regions BA4.

In an embodiment, as illustrated in FIG. 7, each of the third-first power supply voltage horizontal wirings HPL3-1 may be disconnected from each of the fourth-first power supply voltage horizontal wirings HPL4-1.

In an embodiment, as illustrated in FIG. 7, each of the third-second power supply voltage horizontal wirings HPL3-2 may be disconnected from each of the fourth-second power supply voltage horizontal wirings HPL4-2.

Referring to FIG. 8, the display panel PNL may further include at least one power supply voltage vertical wiring. In an embodiment, the power supply voltage vertical wiring may be disposed on the same layer as the fourth conductive layer 1500. For example, the power supply voltage vertical wiring may be disposed on the fourth insulating layer ILD4. That is, the power supply voltage vertical wiring may be disposed on the power supply voltage horizontal wiring.

In an embodiment, as illustrated in FIG. 8, the display panel PNL may include first-first power supply voltage vertical wirings VPL1-1, first-second power supply voltage vertical wirings VPL1-2, second-first power supply voltage vertical wirings VPL2-1, second-second power supply voltage vertical wirings VPL2-2, third-first power supply voltage vertical wirings VPL3-1, third-second power supply voltage vertical wirings VPL3-2, fourth-first power supply voltage vertical wirings VPL4-1, and fourth-second power supply voltage vertical wirings VPL4-2.

In an embodiment, the first-first power supply voltage vertical wirings VPL1-1 may extend in the third direction D3 (e.g., the column direction) and may overlap with the first region LA1.

In an embodiment, the first-second power supply voltage vertical wirings VPL1-2 may extend in the third direction D3 and may overlap with the first boundary regions BA1.

In an embodiment, a number of the first-second power supply voltage vertical wirings VPL1-2 may gradually increase in the direction from the second region LA2 to the first region LA1. That is, the number of the first-second power supply voltage vertical wirings VPL1-2 may gradually increase in the second direction D2.

Specifically, as illustrated in FIG. 8, a number of the first-second power supply voltage vertical wirings VPL1-2 overlapping with the first-first boundary region BA1-1 may be 1, a number of the first-second power supply voltage vertical wirings VPL1-2 overlapping with the first-second boundary region BA1-2 may be 2, a number of the first-second power supply voltage vertical wirings VPL1-2 overlapping with the first-third boundary region BA1-3 may be 3, and a number of the first-second power supply voltage vertical wirings VPL1-2 overlapping with the first-fourth boundary region BA1-4 may be 4. However, the present disclosure is not limited to the aforementioned quantities.

In an embodiment, the second-first power supply voltage vertical wirings VPL2-1 may extend in the third direction D3 and may overlap with the second region LA2.

In an embodiment, the second-second power supply voltage vertical wirings VPL2-2 may extend in the third direction D3 and may overlap with the second boundary regions BA2.

In an embodiment, a number of the second-second power supply voltage vertical wirings VPL2-2 may gradually increase in the direction from the first region LA1 to the second region LA2. That is, the number of the second-second power supply voltage vertical wirings VPL2-2 may gradually increase in the first direction D1.

Specifically, as illustrated in FIG. 8, a number of the second-second power supply voltage vertical wirings VPL2-2 overlapping with the second-first boundary region BA2-1 may be 1, a number of the second-second power supply voltage vertical wirings VPL2-2 overlapping with the second-second boundary region BA2-2 may be 2, a number of the second-second power supply voltage vertical wirings VPL2-2 overlapping with the second-third boundary region BA2-3 may be 3, and a number of the second-second power supply voltage vertical wirings VPL2-2 overlapping with the second-fourth boundary region BA2-4 may be 4. However, the present disclosure is not limited to the aforementioned quantities.

In an embodiment, the third-first power supply voltage vertical wirings VPL3-1 may extend in the third direction D3 and may overlap with the third region LA3.

In an embodiment, the third-second power supply voltage vertical wirings VPL3-2 may extend in the third direction D3 and may overlap with the third boundary regions BA3.

In an embodiment, a number of the third-second power supply voltage vertical wirings VPL3-2 may gradually increase in a direction from the fourth region LA4 to the third region LA3. That is, the number of the third-second power supply voltage vertical wirings VPL3-2 may gradually increase in the second direction D2.

Specifically, as illustrated in FIG. 8, a number of the third-second power supply voltage vertical wirings VPL3-2 overlapping with the third-first boundary region BA3-1 may be 1, a number of the third-second power supply voltage vertical wirings VPL3-2 overlapping with the third-second boundary region BA3-2 may be 2, a number of the third-second power supply voltage vertical wirings VPL3-2 overlapping with the third-third boundary region BA3-3 may be 3, and a number of the third-second power supply voltage vertical wirings VPL3-2 overlapping with the third-fourth boundary region BA3-4 may be 4. However, the present disclosure is not limited to the aforementioned quantities.

In an embodiment, the fourth-first power supply voltage vertical wirings VPL4-1 may extend in the third direction D3 and may overlap with the fourth region LA4.

In an embodiment, the fourth-second power supply voltage vertical wirings VPL4-2 may extend in the third direction D3 and may overlap with the fourth boundary regions BA4.

In an embodiment, a number of the fourth-second power supply voltage vertical wirings VPL4-2 may gradually increase in a direction from the third region LA3 to the fourth region LA4. That is, the number of the fourth-second power supply voltage vertical wirings VPL4-2 may gradually increase in the first direction D1.

Specifically, as illustrated in FIG. 8, a number of the fourth-second power supply voltage vertical wirings VPL4-2 overlapping with the fourth-first boundary region BA4-1 may be 1, a number of the fourth-second power supply voltage vertical wirings VPL4-2 overlapping with the fourth-second boundary region BA4-2 may be 2, a number of the fourth-second power supply voltage vertical wirings VPL4-2 overlapping with the fourth-third boundary region BA4-3 may be 3, and a number of the fourth-second power supply voltage vertical wirings VPL4-2 overlapping with the fourth-fourth boundary region BA4-4 may be 4. However, the present disclosure is not limited to the aforementioned quantities.

Referring to FIG. 9, the power supply voltage horizontal wiring and the power supply voltage vertical wiring may be electrically connected. The power supply voltage horizontal wiring and the power supply voltage vertical wiring, which are electrically connected to each other, may be provided with the same power supply voltage.

In an embodiment, the first-first power supply voltage vertical wirings VPL1-1 may be electrically connected to the first-first power supply voltage horizontal wirings HPL1-1 and the first-second power supply voltage horizontal wirings HPL1-2. In this case, contact holes may be formed at intersections of the first-first power supply voltage vertical wirings VPL1-1 and the first-first power supply voltage horizontal wirings HPL1-1, and contact holes may be formed at intersections of the first-first power supply voltage vertical wirings VPL1-1 and the first-second power supply voltage horizontal wirings HPL1-2.

In an embodiment, the first-second power supply voltage vertical wirings VPL1-2 may be electrically connected to the first-first power supply voltage horizontal wirings HPL1-1. In this case, contact holes may be formed at intersections of the first-second power supply voltage vertical wirings VPL1-2 and the first-first power supply voltage horizontal wirings HPL1-1.

For example, with respect to one first-first power supply voltage horizontal wiring HPL1-1, one contact hole may be formed in the first-first boundary region BA1-1, two contact holes may be formed in the first-second boundary region BA1-2, three contact holes may be formed in the first-third boundary region BA1-3, and four contact holes may be formed in the first-fourth boundary region BA1-4. However, the present disclosure is not limited to the aforementioned quantities.

Contact holes may not be formed at intersections of the first-second power supply voltage vertical wirings VPL1-2 and the second-second power supply voltage horizontal wirings HPL2-2.

Accordingly, the first-first power supply voltage horizontal wirings HPL1-1, the first-second power supply voltage horizontal wirings HPL1-2, the first-first power supply voltage vertical wirings VPL1-1, and the first-second power supply voltage vertical wirings VPL1-2 may be provided with the first power supply voltage ELVDD1.

In an embodiment, the second-first power supply voltage vertical wirings VPL2-1 may be electrically connected to the second-first power supply voltage horizontal wirings HPL2-1 and the second-second power supply voltage horizontal wirings HPL2-2. In this case, contact holes may be formed at intersections of the second-first power supply voltage vertical wirings VPL2-1 and the second-first power supply voltage horizontal wirings HPL2-1, and contact holes may be formed at intersections of the second-first power supply voltage vertical wirings VPL2-1 and the second-second power supply voltage horizontal wirings HPL2-2.

In an embodiment, the second-second power supply voltage vertical wirings VPL2-2 may be electrically connected to the second-first power supply voltage horizontal wirings HPL2-1. In this case, contact holes may be formed at intersections of the second-second power supply voltage vertical wirings VPL2-2 and the second-first power supply voltage horizontal wirings HPL2-1.

For example, with respect to one second-first power supply voltage horizontal wiring HPL2-1, one contact hole may be formed in the second-first boundary region BA2-1, two contact holes may be formed in the second-second boundary region BA2-2, three contact holes may be formed in the second-third boundary region BA2-3, and four contact holes may be formed in the second-fourth boundary region BA2-4. However, the present disclosure is not limited to the aforementioned quantities.

Contact holes may not be formed at intersections of the second-second power supply voltage vertical wirings VPL2-2 and the first-first power supply voltage horizontal wirings HPL1-1.

Accordingly, the second-first power supply voltage horizontal wirings HPL2-1, the second-second power supply voltage horizontal wirings HPL2-2, the second-first power supply voltage vertical wirings VPL2-1, and the second-second power supply voltage vertical wirings VPL2-2 may be provided with the second power supply voltage ELVDD2.

In other words, each area of the boundary regions described above may correspond to a number of the contact holes as described above. For example, in the first-second boundary region BA1-2, the number of the contact holes through which the first-first power supply voltage horizontal wirings HPL1-1 and the first-second power supply voltage vertical wirings VPL1-2 are connected may be 2. In addition, in the first-first boundary region BA1-1, the number of the contact holes through which the first-first power supply voltage horizontal wirings HPL1-1 and the first-second power supply voltage vertical wirings VPL1-2 are connected may be 1. Accordingly, the area of the first-second boundary region BA1-2 may be larger than the area of the first-first boundary region BA1-1.

In an embodiment, a number of the contact holes through which the first-first power supply voltage horizontal wirings HPL1-1 and the first-second power supply voltage vertical wirings VPL1-2 are connected in a first row of the first boundary regions BA1 may be different from a number of the contact holes through which the first-first power supply voltage horizontal wirings HPL1-1 and the first-first power supply voltage vertical wirings

### Vpl1-1 Are Connected in a First Row of the First Region La1.

In an embodiment, a number of the contact holes through which the second-second power supply voltage horizontal wirings HPL2-2 and the second-second power supply voltage vertical wirings VPL2-2 are connected in a second row of the second boundary regions BA2 may be different from a number of the contact holes through which the second-second power supply voltage horizontal wirings HPL2-2 and the second-first power supply voltage vertical wirings VPL2-1 are connected in a second row of the second region LA2.

The number of the contact holes through which the first-first power supply voltage horizontal wirings HPL1-1 and the first-second power supply voltage vertical wirings VPL1-2 are connected in the first row of the first boundary region BA1 may be substantially the same as the number of the contact holes through which the second-second power supply voltage horizontal wirings HPL2-2 and the second-second power supply voltage vertical wirings VPL2-2 are connected in the second row of the second boundary region BA2.

In addition, the number of the contact holes through which the first-first power supply voltage horizontal wirings HPL1-1 and the first-first power supply voltage vertical wirings VPL1-1 are connected in the first row of the first region LA1 may be substantially the same as the number of the contact holes through which the second-second power supply voltage horizontal wirings HPL2-2 and the second-first power supply voltage vertical wirings VPL2-1 are connected in the second row of the second region LA2.

In an embodiment, the number of the contact holes through which the first-first power supply voltage horizontal wirings HPL1-1 and the first-second power supply voltage vertical wirings VPL1-2 are connected in the first row of the first boundary regions BA1 may decrease in the direction from the first region LA1 to the second region LA2.

In this case, the number of the contact holes through which the second-second power supply voltage horizontal wirings HPL2-2 and the second-second power supply voltage vertical wirings VPL2-2 are connected in the second row of the second boundary regions BA2 may increase in the direction from the first region LA1 to the second region LA2.

In another embodiment, the number of the contact holes through which the first-first power supply voltage horizontal wirings HPL1-1 and the first-second power supply voltage vertical wirings VPL1-2 are connected in the first row of the first boundary regions BA1 may increase in the direction from the first region LA1 to the second region LA2.

In this case, the number of the contact holes through which the second-second power supply voltage horizontal wirings HPL2-2 and the second-second power supply voltage vertical wirings VPL2-2 are connected in the second row of the second boundary regions BA2 may decrease in the direction from the first region LA1 to the second region LA2.

The display device DD1 may include the first region LA1, the second region LA2, the first boundary regions BA1, and the second boundary regions BA2. The first region LA1 may be provided with the first power supply voltage ELVDD1, and the second region LA2 may be provided with the second power supply voltage ELVDD2.

The first and second power supply voltages ELVDD1 and ELVDD2 may be adjusted based on a luminance of images displayed in the first and second regions LA1 and LA2. For example, when a luminance of an image displayed in the first region LA1 is lower than a luminance of an image displayed in the second region LA2, the first power supply voltage ELVDD1 may be adjusted to be lower than the second power supply voltage ELVDD2. Accordingly, power consumption of the display device DD1 may be reduced (or improved).

The first and second boundary regions BA1 and BA2 may be disposed between the first region LA1 and the second region LA2.

The first boundary regions BA1 may include the first-first boundary region BA1-1, the first-second boundary region BA1-2, the first-third boundary region BA1-3, and the first-fourth boundary region BA1-4. The first power supply voltage ELVDD1 may be provided to the first-first to first-fourth boundary regions BA1-1, BA1-2, BA1-3, and BA1-4, and each area of the first-first to first-fourth boundary regions BA1-1, BA1-2, BA1-3, and BA1-4 may gradually increase in the second direction D2.

In addition, the second boundary regions BA2 may include the second-first boundary region BA2-1, the second-second boundary region BA2-2, the second-third boundary region BA2-3, and the second-fourth boundary region BA2-4. The second power supply voltage ELVDD2 may be provided to the second-first to second-fourth boundary regions BA2-1, BA2-2, BA2-3, and BA2-4, and each area of the second-first to second-fourth boundary regions BA2-1, BA2-2, BA2-3, and BA2-4 may gradually increase in the first direction D1.

As the first and second boundary regions BA1 and BA2 are disposed between the first region LA1 and the second region LA2, a visible boundary (or referred to as seam-line) between the first region LA1 and the second region LA2 may be visually unnoticeable (or suppressed).

In other words, as the first power supply voltage ELVDD1 is provided to the first region LA1 and the second power supply voltage ELVDD2, which is different from the first power supply voltage ELVDD1, is provided to the second region LA2, luminance and/or color differences may occur between the first region LA1 and the second region LA2. However, in the display device DD1, the luminance and/or color differences which may be visually noticeable to a viewer may be mitigated because each area of the first and second boundary regions BA1 and BA2 is gradually varied.

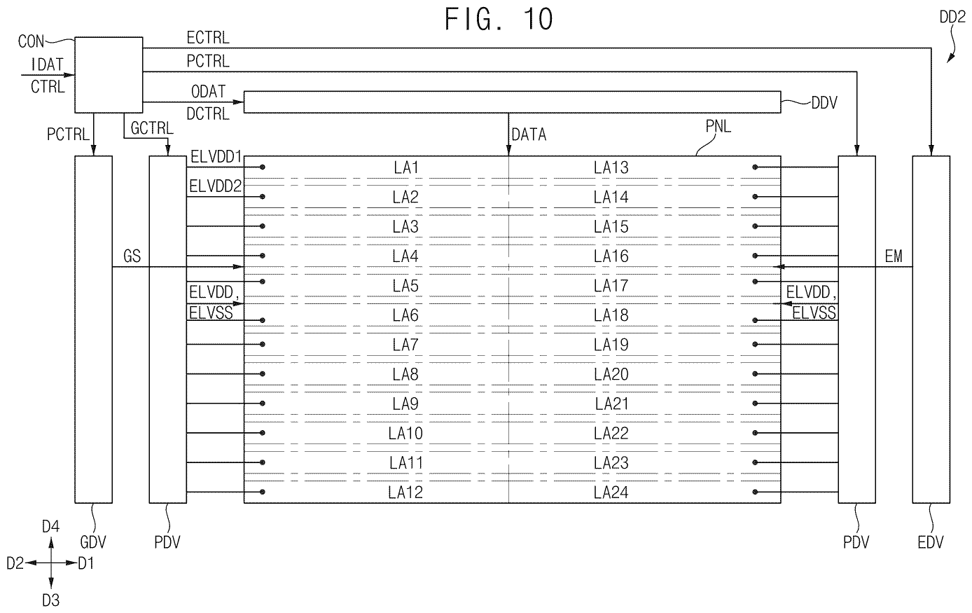

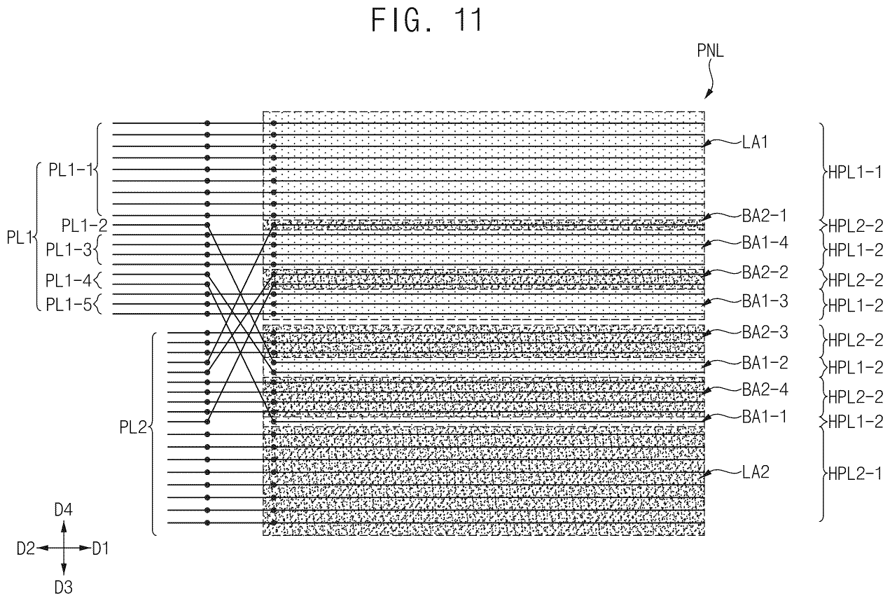

FIG. 10 is a block diagram illustrating still another example of a display device according to one or more embodiments, and FIG. 11 is a view for describing a display panel included in the display device of FIG. 10.

Referring to FIG. 10, a display device DD2 may include a display panel PNL, a data driving circuit DDV, a gate driving circuit GDV, a light-emitting driving circuit EDV, a power supply circuit PDV, and a timing control circuit CON.

The display panel PNL may be electrically connected to the data driving circuit DDV, the gate driving circuit GDV, the light-emitting driving circuit EDV, and the power supply circuit PDV. The display panel PNL may receive voltages and/or signals from the data driving circuit DDV, the gate driving circuit GDV, the light-emitting driving circuit EDV, and the power supply circuit PDV. The display panel PNL may include at least one pixel. The at least one pixel may emit light, and the display panel PNL may display an image.

In an embodiment, the display panel PNL may include at least one region and at least one boundary region.

In an embodiment, as illustrated in FIG. 10, the display panel PNL may include 24 regions. That is, the display panel PNL may include first to twenty-fourth regions LA1, LA2, LA3, LA4, LA5, LA6, LA7, LA8, LA9, LA10, LA11, LA12, LA13, LA14, LA15, LA16, LA17, LA18, LA19, LA20, LA21, LA22, LA23, and LA24.

In an embodiment, the second region LA2 may be adjacent to the first region LA1 in the third direction D3. The third region LA3 may be adjacent to the second region LA2 in the third direction D3. The fourth region LA4 may be adjacent to the third region LA3 in the third direction D3.

In an embodiment, the display panel PNL may include 24 boundary regions. That is, the display panel PNL may include first to twenty-fourth boundary regions.

In an embodiment, as illustrated in FIG. 11, the first and second boundary regions BA1 and BA2 may be disposed between the first region LA1 and the second region LA2. The third and fourth boundary regions BA3 and BA4 may be disposed between the third region LA3 and the fourth region LA4.

However, the present disclosure is not limited thereto. For example, a number and an arrangement of the regions may be appropriately determined. Accordingly, a number and an arrangement of the boundary regions may be determined based on the number and the arrangement of the regions.

In an embodiment, first to twenty-fourth power supply voltages may be provided to the first to twenty-fourth regions LA1, LA2, LA3, LA4, LA5, LA6, LA7, LA8, LA9, LA10, LA11, LA12, LA13, LA14, LA15, LA16, LA17, LA18, LA19, LA20, LA21, LA22, LA23, and LA24, respectively.

In this case, some of the first to twenty-fourth power supply voltages may be the same as each other, and some of the first to twenty-fourth power supply voltages may be different from each other.

For example, the first region LA1 may be provided with the first power supply voltage ELVDD1, the second region LA2 may be provided with the second power supply voltage ELVDD2, and the third region LA3 may be provided with the third power supply voltage ELVDD3. The first power supply voltage ELVDD1 and the second power supply voltage ELVDD2 may be the same as or different from each other, the second power supply voltage ELVDD2 and the third power supply voltage ELVDD3 may be the same as or different from each other, and the first power supply voltage ELVDD1 and the third power supply voltage ELVDD3 may be the same as or different from each other.

The data driving circuit DDV, the gate driving circuit GDV, and the light-emitting driving circuit EDV may be substantially the same as the data driving circuit DDV, the gate driving circuit GDV, and the light-emitting driving circuit EDV described above with reference to FIG. 1.

The power supply circuit PDV may receive a power driving control signal PCTRL from the timing control circuit CON and may generate the power supply voltage ELVDD and the common voltage ELVSS.

In an embodiment, the power supply circuit PDV may be disposed at a left side and/or a right side of the display panel PNL. For example, the power supply circuit PDV may be adjacent to the display panel PNL in the first direction D1 or may be adjacent to the display panel PNL in the third direction D3.

Referring to FIG. 11, the display panel PNL may include a plurality of regions and a plurality of boundary regions. For example, the display panel PNL may include the first region LA1, the second region LA2, the first boundary regions BA1, and the second boundary regions BA2.

In an embodiment, the first boundary regions BA1 may include a plurality of boundary regions. For example, the first boundary regions BA1 may include a first-first boundary region BA1-1, a first-second boundary region BA1-2, a first-third boundary region BA1-3, and a first-fourth boundary region BA1-4.

In an embodiment, the second boundary regions BA2 may include a plurality of boundary regions. For example, the second boundary regions BA2 may include a second-first boundary region BA2-1, a second-second boundary region BA2-2, a second-third boundary region BA2-3, and a second-fourth boundary region BA2-4.

In an embodiment, the second region LA2 may be adjacent to the first region LA1 in the third direction D3. The first boundary regions BA1 may be disposed between the first region LA1 and the second region LA2, and the second boundary regions BA2 may be disposed between the first region LA1 and the second region LA2.

In an embodiment, the first-first boundary region BA1-1, the first-second boundary region BA1-2, the first-third boundary region BA1-3, and the first-fourth boundary region BA1-4 may be arranged in order in a fourth direction D4 opposite to the third direction D3.

In other words, the first-first boundary region BA1-1 may be disposed between the first region LA1 and the second region LA2, the first-second boundary region BA1-2 may be disposed between the first-first boundary region BA1-1 and the first region LA1, the first-third boundary region BA1-3 may be disposed between the first-second boundary region BA1-2 and the first region LA1, and the first-fourth boundary region BA1-4 may be disposed between the first-third boundary region BA1-3 and the first region LA1.

In an embodiment, the second-first boundary region BA2-1, the second-second boundary region BA2-2, the second-third boundary region BA2-3, and the second-fourth boundary region BA2-4 may be arranged in order in the third direction D3.

In other words, the second-first boundary region BA2-1 may be disposed between the first region LA1 and the second region LA2, the second-second boundary region BA2-2 may be disposed between the second-first boundary region BA2-1 and the second region LA2, the second-third boundary region BA2-3 may be disposed between the second-second boundary region BA2-2 and the second region LA2, and the second-fourth boundary region BA2-4 may be disposed between the second-third boundary region BA2-3 and the second region LA2.

In an embodiment, the first-first boundary region BA1-1, the first-second boundary region BA1-2, the first-third boundary region BA1-3, the first-fourth boundary region BA1-4, the second-first boundary region BA2-1, the second-second boundary region BA2-2, the second-third boundary region BA2-3, and the second-fourth boundary region BA2-4 may be arranged alternately with each other.

In other words, the first-first boundary region BA1-1 may be disposed between the second region LA2 and the second-fourth boundary region BA2-4, the first-second boundary region BA1-2 may be disposed between the second-fourth boundary region BA2-4 and the second-third boundary region BA2-3, the first-third boundary region BA1-3 may be disposed between the second-third boundary region BA2-3 and the second-second boundary region BA2-2, and the first-fourth boundary region BA1-4 may be disposed between the second-second boundary region BA2-2 and the second-first boundary region BA2-1.

In an embodiment, the first power supply voltage ELVDD1 may be provided to the first region LA1. That is, pixels disposed in the first region LA1 may be provided with the first power supply voltage ELVDD1.

In an embodiment, the second power supply voltage ELVDD2 may be provided to the second region LA2. That is, pixels disposed in the second region LA2 may be provided with the second power supply voltage ELVDD2. For example, the second power supply voltage ELVDD2 may be different from the first power supply voltage ELVDD1.

In an embodiment, the first power supply voltage ELVDD1 may be provided to the first boundary regions BA1. For example, the first power supply voltage ELVDD1 may be provided to the first-first boundary region BA1-1, the first-second boundary region BA1-2, the first-third boundary region BA1-3, and the first-fourth boundary region BA1-4. That is, pixels disposed in the first-first boundary region BA1-1, the first-second boundary region BA1-2, the first-third boundary region BA1-3, and the first-fourth boundary region BA1-4 may be provided with the first power supply voltage ELVDD1.

In an embodiment, the second power supply voltage ELVDD2 may be provided to the second boundary regions BA2. For example, the second power supply voltage ELVDD2 may be provided to the second-first boundary region BA2-1, the second-second boundary region BA2-2, the second-third boundary region BA2-3, and the second-fourth boundary region BA2-4. That is, pixels disposed in the second-first boundary region BA2-1, the second-second boundary region BA2-2, the second-third boundary region BA2-3, and the second-fourth boundary region BA2-4 may be provided with the second power supply voltage ELVDD2.

In an embodiment, each area of the first boundary regions BA1 may gradually increase in a direction from the second region LA2 to the first region LA1. That is, each area of the first boundary regions BA1 may gradually increase in the fourth direction D4.

For example, the area of the first-second boundary region BA1-2 may be larger than the area of the first-first boundary region BA1-1. That is, a number of pixels disposed in the first-second boundary region BA1-2 may be greater than a number of pixels disposed in the first-first boundary region BA1-1.

For example, an area of the first-third boundary region BA1-3 may be larger than an area of the first-second boundary region BA1-2. That is, a number of pixels disposed in the first-third boundary region BA1-3 may be greater than the number of the pixels disposed in the first-second boundary region BA1-2.

For example, an area of the first-fourth boundary region BA1-4 may be larger than the area of the first-third boundary region BA1-3. That is, a number of pixels disposed in the first-fourth boundary region BA1-4 may be greater than the number of the pixels disposed in the first-third boundary region BA1-3.

In addition, an area of the first region LA1 may be larger than the area of the first-fourth boundary region BA1-4. That is, a number of the pixels disposed in the first region LA1 may be greater than the number of the pixels disposed in the first-fourth boundary region BA1-4.

In an embodiment, each area of the second boundary regions BA2 may gradually increase in a direction from the first region LA1 to the second region LA2. That is, each area of the second boundary regions BA2 may gradually increase in the third direction D3.

For example, an area of the second-second boundary region BA2-2 may be larger than an area of the second-first boundary region BA2-1. That is, a number of pixels disposed in the second-second boundary region BA2-2 may be greater than a number of pixels disposed in the second-first boundary region BA2-1.

For example, an area of the second-third boundary region BA2-3 may be larger than the area of the second-second boundary region BA2-2. That is, a number of pixels disposed in the second-third boundary region BA2-3 may be greater than the number of the pixels disposed in the second-second boundary region BA2-2.

For example, an area of the second-fourth boundary region BA2-4 may be larger than the area of the second-third boundary region BA2-3. That is, number of pixels disposed in the second-fourth boundary region BA2-4 may be greater than the number of the pixels disposed in the second-third boundary region BA2-3.

In addition, an area of the second region LA2 may be larger than the area of the second-fourth boundary region BA2-4. That is, a number of the pixels disposed in the second region LA2 may be greater than the number of the pixels disposed in the second-fourth boundary region BA2-4.

In an embodiment, the area of the first region LA1 may be substantially equal to the area of the second region LA2.

In addition, the area of the first-first boundary region BA1-1 may be substantially equal to the area of the second-first boundary region BA2-1, the area of the first-second boundary region BA1-2 may be substantially equal to the area of the second-second boundary region BA2-2, the area of the first-third boundary region BA1-3 may be substantially equal to the area of the second-third boundary region BA2-3, and the area of the first-fourth boundary region BA1-4 may be substantially equal to the area of the second-fourth boundary region BA2-4.

Referring to FIG. 11, the display panel PNL may further include at least one power supply voltage horizontal wiring.

In an embodiment, the display panel PNL may include first-first power supply voltage horizontal wirings HPL1-1, first-second power supply voltage horizontal wirings HPL1-2, second-first power supply voltage horizontal wirings HPL2-1, and second-second power supply voltage horizontal wirings HPL2-2.

In an embodiment, the first-first power supply voltage horizontal wirings HPL1-1 may extend in the first direction D1 (e.g., the row direction) and may overlap with the first region LA1.

In an embodiment, the first-second power supply voltage horizontal wirings HPL1-2 may extend in the first direction D1 (e.g., the row direction) and may overlap with the first boundary regions BA1.

In an embodiment, the first-first power supply voltage horizontal wirings HPL1-1 and the first-second power supply voltage horizontal wirings HPL1-2 may be provided with the first power supply voltage ELVDD1.

In an embodiment, the second-first power supply voltage horizontal wirings HPL2-1 may extend in the first direction D1 (e.g., the row direction) and may overlap with the second region LA2.

In an embodiment, the second-second power supply voltage horizontal wirings HPL2-2 may extend in the first direction D1 (e.g., the row direction) and may overlap with the second boundary regions BA2.

In an embodiment, the second-first power supply voltage horizontal wirings HPL2-1 and the second-second power supply voltage horizontal wirings HPL2-2 may be provided with the second power supply voltage ELVDD2.

In an embodiment, a number of the first-second power supply voltage horizontal wirings HPL1-2 may gradually increase in the direction from the second region LA2 to the first region LA1. That is, the number of the first-second power supply voltage horizontal wirings HPL1-2 may gradually increase in the fourth direction D4.

Specifically, as illustrated in FIG. 11, a number of the first-second power supply voltage horizontal wirings HPL1-2 overlapping with the first-first boundary region BA1-1 may be 1, a number of the first-second power supply voltage horizontal wirings HPL1-2 overlapping with the first-second boundary region BA1-2 may be 2, a number of the first-second power supply voltage horizontal wirings HPL1-2 overlapping with the first-third boundary region BA1-3 may be 3, and a number of the first-second power supply voltage horizontal wirings HPL1-2 overlapping with the first-fourth boundary region BA1-4 may be 4.

In an embodiment, a number of the second-second power supply voltage horizontal wirings HPL2-2 may gradually increase in the direction from the first region LA1 to the second region LA2. That is, the number of the second-second power supply voltage horizontal wirings HPL2-2 may gradually increase in the third direction D3.

Specifically, as illustrated in FIG. 11, a number of the second-second power supply voltage horizontal wirings HPL2-2 overlapping with the second-first boundary region BA2-1 may be 1, a number of the second-second power supply voltage horizontal wirings HPL2-2 overlapping with the second-second boundary region BA2-2 may be 2, a number of the second-second power supply voltage horizontal wirings HPL2-2 overlapping with the second-third boundary region BA2-3 may be 3, and a number of the second-second power supply voltage horizontal wirings HPL2-2 overlapping with the second-fourth boundary region BA2-4 may be 4.

In an embodiment, the power supply circuit PDV may include at least one power supply voltage supply-line. For example, the power supply circuit PDV may include twelve power supply voltage supply-lines. For example, as illustrated in FIG. 11, the power supply circuit PDV may include first power supply voltage supply-lines PL1 and second power supply voltage supply-lines PL2.

The first power supply voltage supply-lines PL1 may extend in the first direction D1 and may provide the first power supply voltage ELVDD1.

In an embodiment, the first power supply voltage supply-lines PL1 may include first-first power supply voltage supply-lines PL1-1, first-second power supply voltage supply-lines PL1-2, first-third power supply voltage supply-lines PL1-3, first-fourth power supply voltage supply-lines PL1-4, and first-fifth power supply voltage supply-lines PL1-5.

In an embodiment, the first-first power supply voltage supply-lines PL1-1 may provide the first power supply voltage ELVDD1 to the first region LA1. For example, the first-first power supply voltage supply-lines PL1-1 may be electrically connected to the first-first power supply voltage horizontal wirings HPL1-1.

In an embodiment, the first-second power supply voltage supply-lines PL1-2 may provide the first power supply voltage ELVDD1 to the first-second boundary region BA1-2. For example, the first-second power supply voltage supply-lines PL1-2 may be electrically connected to the first-second power supply voltage horizontal wirings HPL1-2 overlapping with the first-second boundary region BA1-2.

In an embodiment, the first-third power supply voltage supply-lines PL1-3 may provide the first power supply voltage ELVDD1 to the first-fourth boundary region BA1-4. For example, the first-third power supply voltage supply-lines PL1-3 may be electrically connected to the first-second power supply voltage horizontal wirings HPL1-2 overlapping with the first-fourth boundary region BA1-4.

In an embodiment, the first-fourth power supply voltage supply-lines PL1-4 may provide the first power supply voltage ELVDD1 to the first-first boundary region BA1-1 and the first-second boundary region BA1-2. For example, the first-fourth power supply voltage supply-lines PL1-4 may be electrically connected to the first-second power supply voltage horizontal wirings HPL1-2 overlapping with the first-first boundary region BA1-1 and to the first-second power supply voltage horizontal wirings HPL1-2 overlapping with the first-second boundary region BA1-2.

In an embodiment, the first-fifth power supply voltage supply-lines PL1-5 may provide the first power supply voltage ELVDD1 to the first-third boundary region BA1-3. For example, the first-fifth power supply voltage supply-lines PL1-5 may be electrically connected to the first-second power supply voltage horizontal wirings HPL1-2 overlapping with the first-third boundary region BA1-3.

In an embodiment, the first-first, first-second, first-third, first-fourth, and first-fifth power supply voltage supply-lines PL1-1, PL1-2, PL1-3, PL1-4, and PL1-5 may be arranged in order in the third direction D3. For example, the first-second power supply voltage supply-lines PL1-2 may be disposed between the first-first power supply voltage supply-lines PL1-1 and the first-third power supply voltage supply-lines PL1-3, and the first-fourth power supply voltage supply-lines PL1-4 may be disposed between the first-third power supply voltage supply-lines PL1-3 and the first-fifth power supply voltage supply-lines PL1-5.

In an embodiment, the first-first power supply voltage supply-lines PL1-1 may be electrically connected to the first-first power supply voltage horizontal wirings HPL1-1. In this case, in the first region LA1, the first-first power supply voltage supply-lines PL1-1 may be connected to the first-first power supply voltage horizontal wirings HPL1-1 through contact holes.

The first-second power supply voltage supply-lines PL1-2 may be electrically connected to the first-second power supply voltage horizontal wirings HPL1-2 in the first-second boundary region BA1-2. In this case, in the first-second boundary region BA1-2, the first-second power supply voltage supply-lines PL1-2 may be connected to the first-second power supply voltage horizontal wirings HPL1-2 through contact holes.

The first-third power supply voltage supply-lines PL1-3 may be electrically connected to the first-second power supply voltage horizontal wirings HPL1-2 in the first-fourth boundary region BA1-4. In this case, in the first-fourth boundary region BA1-4, the first-third power supply voltage supply-lines PL1-3 may be connected to the first-second power supply voltage horizontal wirings HPL1-2 through contact holes.

The first-fourth power supply voltage supply-lines PL1-4 may be electrically connected to the first-second power supply voltage horizontal wirings HPL1-2 in the first-second boundary region BA1-2 and the first-first boundary region BA1-1. In this case, in the first-second boundary region BA1-2 and the first-first boundary region BA1-1, the first-fourth power supply voltage supply-lines PL1-4 may be connected to the first-second power supply voltage horizontal wirings HPL1-2 through contact holes.

The first-fifth power supply voltage supply-lines PL1-5 may be electrically connected to the first-second power supply voltage horizontal wirings HPL1-2 in the first-third boundary region BA1-3. In this case, in the first-third boundary region BA1-3, the first-fifth power supply voltage supply-lines PL1-5 may be connected to the first-second power supply voltage horizontal wirings HPL1-2 through contact holes.

Each area of the boundary regions described above may correspond to a number of the contact holes described above. For example, a number of the contact holes through which the first power supply voltage supply-lines PL1 and the first-second power supply voltage horizontal wirings HPL1-2 are connected in the first-first boundary region BA1-1 may be 1. A number of the contact holes through which the first power supply voltage supply-lines PL1 and the first-second power supply voltage horizontal wirings HPL1-2 are connected in the first-second boundary region BA1-2 may be 2. A number of the contact holes through which the first power supply voltage supply-lines PL1 and the first-second power supply voltage horizontal wirings HPL1-2 are connected in the first-third boundary region BA1-3 may be 3. A number of the contact holes through which the first power supply voltage supply-lines PL1 and the first-second power supply voltage horizontal wirings HPL1-2 are connected in the first-fourth boundary region BA1-4 may be 4.

In an embodiment, a number of the contact holes through which the first power supply voltage supply-lines PL1 and the first-second power supply voltage horizontal wirings HPL1-2 are connected may decrease in the direction from the first region LA1 to the second region LA2. In an embodiment, a number of the contact holes through which the second power supply voltage supply-lines PL2 and the second-second power supply voltage horizontal wirings HPL2-2 are connected may increase in the direction from the first region LA1 to the second region LA2.

The display device DD2 may include the first region LA1, the second region LA2, the first boundary regions BA1, and the second boundary regions BA2. The first region LA1 may be provided with the first power supply voltage ELVDD1, and the second region LA2 may be provided with the second power supply voltage ELVDD2.

The first and second power supply voltages ELVDD1 and ELVDD2 may be adjusted based on a luminance of images displayed in the first and second regions LA1 and LA2. For example, when a luminance of an image displayed in the first region LA1 is lower than a luminance of an image displayed in the second region LA2, the first power supply voltage ELVDD1 may be adjusted to be lower than the second power supply voltage ELVDD2. Accordingly, power consumption of the display device DD2 may be reduced (or improved).

Additionally, the first and second boundary regions BA1 and BA2 may be disposed between the first region LA1 and the second region LA2.

The first boundary regions BA1 may include the first-first to first-fourth boundary regions BA1-1, BA1-2, BA1-3, and BA1-4. The first power supply voltage ELVDD1 may be provided to the first-first to first-fourth boundary regions BA1-1, BA1-2, BA1-3, and BA1-4. Each area of the first-first to first-fourth boundary regions BA1-1, BA1-2, BA1-3, and BA1-4 may gradually increase in the fourth direction D4.

Additionally, the second boundary regions BA2 may include the second-first to second-fourth boundary regions BA2-1, BA2-2, BA2-3, and BA2-4. The second power supply voltage ELVDD2 may be provided to the second-first to second-fourth boundary regions BA2-1, BA2-2, BA2-3, and BA2-4. Each area of the second-first to second-fourth boundary regions BA2-1, BA2-2, BA2-3, and BA2-4 may gradually increase in the third direction D3.

As the first and second boundary regions BA1 and BA2 are disposed between the first region LA1 and the second region LA2, a visible boundary (or referred to as seam-line) between the first region LA1 and the second region LA2 may be visually unnoticeable (or suppressed).

In other words, as the first power supply voltage ELVDD1 is provided to the first region LA1 and the second power supply voltage ELVDD2, which is different from the first power supply voltage ELVDD1, is provided to the second region LA2, luminance and/or color differences may occur between the first region LA1 and the second region LA2. However, in the display device DD2, the luminance and/or color differences which may be visually noticeable to a viewer may be mitigated because each area of the first and second boundary regions BA1 and BA2 is gradually varied.

The display device according to one or more embodiments may be applied to various electronic devices. An electronic device according to one or more embodiments may include the display device described above and may further include a module or a device which has another additional function.

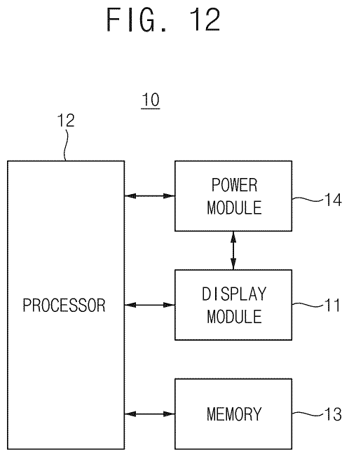

FIG. 12 is a block diagram illustrating an electronic device according to one or more embodiments.

Referring to FIG. 12, the electronic device 10 may include a display module (or display device) 11, at least one processor 12, a memory 13, and a power module (or power supply) (e.g., power circuitry) 14.

The at least one processor 12 may include at least one of a central processing unit (CPU), an application processor (AP), a graphics processing unit (GPU), a communication processor (CP), an image signal processor (ISP), and a controller. In an embodiment, the at least one processor 12 may include two or more parts from a functional or structural perspective. For example, the at least one processor 12 may include a main processor (e.g., a first driving chip) that includes the central processing unit and an auxiliary processor (e.g., a second driving chip) that includes a controller configured to receive an image signal from the main processor and to process the image signal to be compatible with interface specifications of the display module 11.

The memory 13 may include at least one of a non-volatile memory or a volatile memory. The memory 13 may store data information for an operation of the at least one processor 12 or the display module 11. When the at least one processor 12 executes an application stored in the memory 13, an image data signal and/or an input control signal may be transferred to the display module 11, and the display module 11 may output image information through a display screen by processing the received signal. The display module 11 may include, for example but not limited to, organic light emitting diodes, quantum-dot organic light emitting diodes, micro-light-emitting diodes, nano-light-emitting diodes, liquid crystals, and/or the like.

The power module 14 may include a power supply module such as a power adapter, a battery device, and the like and a power conversion module that converts power supplied by the power supply module to generate power for an operation of the electronic device 10. The power conversion performed by the power conversion module may include the DC-DC conversion, the AC-DC conversion, and the DC-AC conversion. However, the power conversion performed by the power conversion module is not limited thereto.

At least one of the components of the electronic device 10 described above may be included in the display device described above. In addition, some of the individual modules functionally included in one module may be included in the display device, and others may be provided separately from the display device. For example, the display device may include the display module 11 and the auxiliary processor of the at least one processor 12, and the main processor of the at least one processor 12, the memory 13, and the power module 14 may be provided in the form of other devices within the electronic device 10 other than the display device. For another example, the power module 14 may be included in the display device, and the power module 14 may provide the power to the at least one processor 12 and the memory 13, which are not included in the display device, within the electronic device 10. However, the present disclosure is not limited thereto.

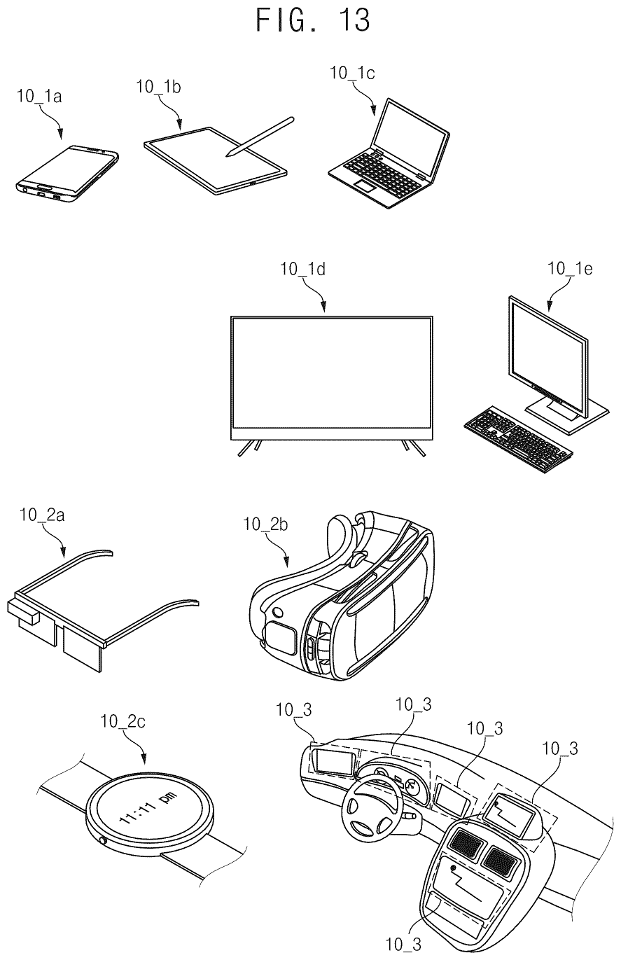

FIG. 13 is a schematic diagram of an electronic device according to various embodiments.

Referring to FIG. 13, various electronic devices to which the display device according to one or more embodiments is applied may include image display electronic devices including display modules such as a smart phone 10_1a, a tablet personal computer (PC) 10_1b, a laptop 10_1c, a television (TV) 101_1d, and a desk monitor 101_1e, wearable electronic devices including display modules such as smart glasses 10_2a, a head mounted display (HMD) 10_2b, and a smart watch 10_2c, and vehicle electronic devices 10_3 including display modules such as a room mirror display and a center information display (CID) arranged on an instrument panel, a center fascia, and a dashboard of an automobile.

The electronic device of FIG. 13 may include components shown in FIG. 12. For example, the smartphone 10_1a may include the display module 11, the at least one processor 12, the memory 13, and the power module 14 shown in FIG. 12. The smartphone 10_1a may further include a communication module and a battery device. Power provided from the battery device may be converted through the power module 14 and provided to the at least one processor 12, the memory 13, and the display module 11. In an embodiment, the display device applied to the smartphone 10_1a may include the display module 11 and may further include the power module 14. The at least one processor 12 and the memory 13 may be provided in the form of chips mounted on a motherboard which is an external device, but are not limited thereto.

According to example embodiments of the present disclosure, a display device may include a first region, a second region, first boundary regions, and second boundary regions. A first power supply voltage may be provided to the first region, and a second power supply voltage may be provided to the second region.

The first and second power supply voltages may be adjusted based on the luminance of images displayed in the first and second regions. For example, when the luminance of the image displayed in the first region is lower than the luminance of the image displayed in the second region, the first power supply voltage may be adjusted to be lower than the second power supply voltage. As a result, power consumption of the display device may be reduced.

In addition, the first and second boundary regions may be disposed between the first region and the second region.

The first boundary regions may include first-first to first-fourth boundary regions. The first power supply voltage may be supplied to the first-first to first-fourth boundary regions. Each area of the first-first to first-fourth boundary regions may gradually increase in a direction from the second region to the first region.

The second boundary regions may include second-first to second-fourth boundary regions. The second power supply voltage may be supplied to the second-first to second-fourth boundary regions. Each area of the second-first to second-fourth boundary regions may gradually increase in a direction from the first region to the second region.

As the first and second boundary regions are disposed between the first region and the second region, a seam-line between the first region and the second region may be visually unnoticeable.

In other words, as the first power supply voltage is provided to the first region and the second power supply voltage is provided to the second region, luminance and/or color differences may occur between the first region and the second region. However, in the display device according to embodiments, the luminance and/or color differences which may be visually noticeable to a viewer may be mitigated because each area of the first and second boundary regions is gradually varied.

At least one of the components, elements, modules or units (collectively “components” in this paragraph) represented by a block or an equivalent indication in the drawings may be implemented or embodied by analog and/or digital circuits including one or more of a logic gate, an integrated circuit, a microprocessor, a microcontroller, a memory circuit, a passive electronic component, an active electronic component, an optical component, and the like. Alternatively or additionally, these components may be implemented or embodied by software including one or more instructions stored in an internal or external storage medium that is readable by at least one processor. For example, the at least one processor may invoke at least one of the one or more instructions stored in the storage medium, and execute it, with or without using one or more other components under the control of the at least one processor. This allows the at least one processor to perform at least one function or operation described above as being performed by each of the components according to the at least one instruction invoked. Here, the at least one processor may include a central processing unit, a graphic processing unit, another type of microprocessor, not being limited thereto.

As described above, although the present disclosure has been described with reference to various example embodiments, it will be understood by those skilled in the art that the present disclosure may be changed or modified within the scope of the present disclosure described in the appended claims.

The present disclosure may be applied to a display device and an electronic device including the display device. For example, the present disclosure may be applied to a smart phone, a cellular phone, a video phone, a smart pad, a smart watch, a tablet PC, a car navigation system, a television, a computer monitor, a laptop, a digital camera, a head mounted display device, etc.

The foregoing is illustrative of example embodiments and is not to be construed as limiting thereof. Although a few embodiments have been described, those skilled in the art will readily appreciate that many modifications are possible in the embodiments without materially departing from the novel teachings and advantages of the present disclosure. Accordingly, all such modifications are intended to be included within the scope of the present disclosure as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a first power supply voltage wiring in a first region of a display panel, the first power supply voltage wiring configured to provide a first power supply voltage, and extending in a row direction;
a second power supply voltage wiring in a second region of the display panel, the second power supply voltage wiring configured to provide a second power supply voltage, and extending in the row direction; and
a plurality of power supply voltage supply-lines in the first region, the second region, and a boundary region between the first region and the second region, the plurality of power supply voltage supply-lines extending in a column direction,
wherein a number of first contact holes connecting the first power supply voltage wiring and the plurality of power supply voltage supply-lines in a first row of the boundary region is different from a number of second contact holes connecting the first power supply voltage wiring and the plurality of power supply voltage supply-lines in a first row of the first region, and
wherein a number of third contact holes connecting the second power supply voltage wiring and the plurality of power supply voltage supply-lines in a second row of the boundary region is different from a number of fourth contact holes connecting the second power supply voltage wiring and the plurality of power supply voltage supply-lines in a second row of the second region.

2. The display device of claim 1, wherein the number of the first contact holes is equal to the number of the third contact holes.

3. The display device of claim 1, wherein the number of the second contact holes is equal to the number of the fourth contact holes.

4. The display device of claim 1, wherein the first power supply voltage is different from the second power supply voltage.

5. The display device of claim 1, wherein the first power supply voltage is the same as the second power supply voltage.

6. The display device of claim 1, wherein the number of the first contact holes decreases in a direction from the first region to the second region.

7. The display device of claim 6, wherein the number of the third contact holes increases in the direction from the first region to the second region.

8. The display device of claim 1, wherein the number of the first contact holes increases in a direction from the first region to the second region.

9. The display device of claim 8, wherein the number of the third contact holes decreases in the direction from the first region to the second region.

10. The display device of claim 1, further comprising:
a plurality of connection conductive patterns between the first power supply voltage wiring and the plurality of power supply voltage supply-lines,
wherein the plurality of connection conductive patterns are on the first power supply voltage wiring,
wherein the plurality of power supply voltage supply-lines are on the plurality of connection conductive patterns, and
wherein the first to fourth contact holes are formed using the plurality of connection conductive patterns.

11. The display device of claim 10, wherein a connection conductive pattern of the plurality of connection conductive patterns is in contact with the first power supply voltage wiring and a power supply voltage supply-line of the plurality of power supply voltage supply-lines.

12. A display device comprising:
a plurality of first-first power supply voltage wirings in a first region of a display panel, the plurality of first-first power supply voltage wirings configured to provide a first power supply voltage, and extending in a row direction;
a plurality of second-first power supply voltage wirings in a second region of the display panel, the plurality of second-first power supply voltage wirings configured to provide a second power supply voltage, and extending in the row direction;
a plurality of first-second power supply voltage wirings in a boundary region between the first region and the second region, the plurality of first-second power supply voltage wirings and extending in the row direction; and
a plurality of first power supply voltage supply-lines configured to provide the first power supply voltage to the plurality of first-first power supply voltage wirings and the plurality of first-second power supply voltage wirings,
wherein, in the boundary region, a number of first contact holes connecting the plurality of first power supply voltage supply-lines and the plurality of first-second power supply voltage wirings decreases in a direction from the first region to the second region.

13. The display device of claim 12, further comprising:
a plurality of second-second power supply voltage wirings in the boundary region, the plurality of second-second power supply voltage wirings extending in the row direction; and
a plurality of second power supply voltage supply-lines configured to provide the second power supply voltage to the plurality of second-first power supply voltage wirings and the plurality of second-second power supply voltage wirings,
wherein, in the boundary region, a number of second contact holes connecting the plurality of second power supply voltage supply-lines and the plurality of second-second power supply voltage wirings increases in the direction from the first region to the second region.

14. An electronic device comprising:
a display device configured to display an image; and
a power supply configured to supply power supply voltages to the display device,
wherein the display device comprises:
a first power supply voltage wiring in a first region of a display panel, the first power supply voltage wiring configured to provide a first power supply voltage, and extending in a row direction;
a second power supply voltage wiring in a second region of the display panel, the second power supply voltage wiring configured to provide a second power supply voltage, and extending in the row direction; and
a plurality of power supply voltage supply-lines in the first region, the second region, and a boundary region between the first region and the second region, the plurality of power supply voltage supply-lines extending in a column direction,
wherein a number of first contact holes connecting the first power supply voltage wiring and the plurality of power supply voltage supply-lines in a first row of the boundary region is different from a number of second contact holes connecting the first power supply voltage wiring and the plurality of power supply voltage supply-lines in a first row of the first region, and
wherein a number of third contact holes connecting the second power supply voltage wiring and the plurality of power supply voltage supply-lines in a second row of the boundary region is different from a number of fourth contact holes connecting the second power supply voltage wiring and the plurality of power supply voltage supply-lines in a second row of the second region.

15. The electronic device of claim 14, wherein the power supply is in an inside the display device.

16. The electronic device of claim 14, wherein the power supply is in an outside of the display device.

17. The electronic device of claim 14, wherein the number of the first contact holes is equal to the number of the third contact holes, and
wherein the number of the second contact holes is equal to the number of the fourth contact holes.

18. The electronic device of claim 14, wherein the first power supply voltage is different from the second power supply voltage.

19. The electronic device of claim 14, wherein the first power supply voltage is the same as the second power supply voltage.

20. The electronic device of claim 14, wherein the number of the first contact holes decreases in a direction from the first region to the second region, and
wherein the number of the third contact holes increases in the direction from the first region to the second region.
